(19) United States
(12) Patent Application Publication
(10) Pub. No.: US 2025/0203929 A1
(43) Pub. Date: Jun. 19, 2025

(54) SEMICONDUCTOR DEVICE

(71) Applicant: SAMSUNG ELECTRONICS CO., LTD., SUWON-SI (KR)

(72) Inventors: HONGSIK SHIN, Suwon-si (KR); Kyongbeom KOH, Suwon-si (KR); Eunkyung KO, Suwon-si (KR); Dongsoo SEO, Suwon-si (KR); Jeongyeon SEO, Suwon-si (KR); WONHYUK LEE, Suwon-si (KR)

(21) Appl. No.: 18/736,228

(22) Filed: Jun. 6, 2024

(30) Foreign Application Priority Data
Dec. 19, 2023 (KR) 10-2023-0185613

(51) Int. Cl. H01L 29/417; H01L 29/06; H01L 29/08; H01L 29/40; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 62/151; H10D 64/01

(57) ABSTRACT

A semiconductor device includes a first active pattern that extends in a first direction, a second active pattern spaced apart from the first active pattern in a second direction that crosses the first direction, a first source/drain pattern disposed on the first active pattern, a second source/drain pattern disposed on the second active pattern, a first active contact electrically connected to the first source/drain pattern, a second active contact electrically connected to the second source/drain pattern, and an insulating structure disposed between the first and second active contacts. The insulating structure includes a first insulating layer and a second insulating layer disposed on the first insulating layer, and each of the first and second insulating layers are in contact with the first and second active contacts.

### CROSS-REFERENCE TO RELATED APPLICATIONS

This U.S. non-provisional patent application claims priority under 35 U.S.C. § 119 from Korean Patent Application No. 10-2023-0185613, filed on Dec. 19, 2023 in the Korean Intellectual Property Office, the contents of which are herein incorporated by reference in their entirety.

### TECHNICAL FIELD

Embodiments of the present disclosure are directed to a semiconductor device, and in particular, to a semiconductor device that includes an insulating structure.

### DISCUSSION OF THE RELATED ART

A semiconductor device includes an integrated circuit that includes metal-oxide-semiconductor field-effect transistors (MOS-FETs). To meet an increasing demand for a semiconductor device with a small pattern size and a reduced design rule, MOS-FETs are being aggressively scaled down. The scale-down of a MOS-FETs can cause deterioration of operational properties of the semiconductor device.

### SUMMARY

An embodiment of the inventive concept provides a semiconductor device with improved electrical characteristics.

According to an embodiment of the inventive concept, a semiconductor device includes a first active pattern that extends in a first direction, a second active pattern spaced apart from the first active pattern in a second direction that crosses the first direction, a first source/drain pattern disposed on the first active pattern, a second source/drain pattern disposed on the second active pattern, a first active contact electrically connected to the first source/drain pattern, a second active contact electrically connected to the second source/drain pattern, and an insulating structure disposed between the first and second active contacts. The insulating structure includes a first insulating layer and a second insulating layer disposed on the first insulating layer, and each of the first and second insulating layers are in contact with the first and second active contacts.

According to an embodiment of the inventive concept, a semiconductor device includes a first active pattern that extends in a first direction, a second active pattern spaced apart from the first active pattern in a second direction that crosses the first direction, a first source/drain pattern disposed on the first active pattern, a second source/drain pattern disposed on the second active pattern, a first active contact electrically connected to the first source/drain pattern, a second active contact electrically connected to the second source/drain pattern, and an insulating structure disposed between the first and second active contacts. The insulating structure includes a first insulating layer and a second insulating layer disposed on the first insulating layer. The second insulating layer includes a first surface in contact with the first insulating layer and a second surface in contact with the first and second active contacts.

According to an embodiment of the inventive concept, a semiconductor device includes a first active pattern that extends in a first direction, a second active pattern spaced apart from the first active pattern in a second direction that crosses the first direction, a first source/drain pattern disposed on the first active pattern, a second source/drain pattern disposed on the second active pattern, a first active contact electrically connected to the first source/drain pattern, a second active contact electrically connected to the second source/drain pattern, a device isolation layer disposed on the first and second active patterns, a first interlayer insulating layer disposed on the first source/drain pattern, the second source/drain pattern, and the device isolation layer, a second interlayer insulating layer disposed on the first interlayer insulating layer, and an insulating structure disposed between the first and second active contacts. The insulating structure includes a first insulating layer and a second insulating layer disposed on the first insulating layer, and each of the first and second active contacts includes a conductive pattern and a barrier layer that encloses the conductive pattern. The first insulating layer includes an inner surface in contact with the second insulating layer, a curved surface in contact with the first and second interlayer insulating layers, and a connection surface that connects the inner surface to the curved surface. The connection surface of the first insulating layer is in contact with the barrier layers of the first and second active contacts.

### BRIEF DESCRIPTION OF THE DRAWINGS

FIGS. 1 to 3 illustrate logic cells of a semiconductor device according to an embodiment of the inventive concept.

FIG. 4 is a plan view of a semiconductor device according to an embodiment of the inventive concept.

FIG. 5A is a cross-sectional view taken along a line A-A′ of FIG. 4.

FIG. 5B is a cross-sectional view taken along a line B-B′ of FIG. 4.

FIG. 5C is a cross-sectional view taken along a line C-C′ of FIG. 4.

FIG. 5D is an enlarged cross-sectional view of a portion E1 of FIG. 5A.

FIG. 5E is an enlarged cross-sectional view of a portion E2 of FIG. 5B.

FIG. 5F is an enlarged cross-sectional view of a portion E3 of FIG. 5C.

FIG. 6 is an enlarged view of a semiconductor device according to an embodiment of the inventive concept.

FIG. 7A is a sectional view of a semiconductor device according to an embodiment of the inventive concept.

FIG. 7B is an enlarged view of a semiconductor device according to an embodiment of the inventive concept.

FIG. 8 is a sectional view of a semiconductor device according to an embodiment of the inventive concept.

FIGS. 9A, 9B, 9C, 10A, 10B, 10C, 11A, 11B, 11C, 12A, 12B, and 12C are sectional views that illustrate a method of fabricating a semiconductor device, according to an embodiment of the inventive concept.

FIG. 13A is a sectional view of a semiconductor device according to an embodiment of the inventive concept.

FIG. 13B is a sectional view of a semiconductor device according to an embodiment of the inventive concept.

### DETAILED DESCRIPTION

Embodiments of the inventive concepts will now be described more fully with reference to the accompanying drawings, in which embodiments are shown. In this specification, when a component is described as being in contact with another component, the component is in direct contact with the other component.

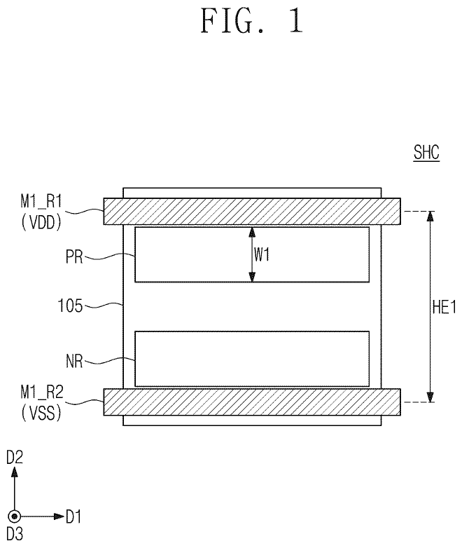

FIGS. 1 to 3 illustrate logic cells of a semiconductor device according to an embodiment of the inventive concept.

Referring to FIG. 1, in an embodiment, a single height cell SHC is provided. For example, a first power line M1_R1 and a second power line M1_R2 are provided on a substrate 105. The first power line M1_R1 is a conduction path to which a drain voltage VDD, such as a power voltage, is provided. The second power line M1_R2 is a conduction path to which a source voltage VSS, such as a ground voltage, is provided.

The single height cell SHC is disposed between the first power line M1_R1 and the second power line M1_R2. The single height cell SHC includes one PMOSFET region PR and one NMOSFET region NR. For example, the single height cell SHC includes a CMOS structure between the first and second power lines M1_R1 and M1_R2.

Each of the PMOSFET and NMOSFET regions PR and NR has a first width W1 in a second direction D2. A length of the single height cell SHC in the second direction D2 may be defined as a first height HE1. The first height HEL is substantially equal to a distance, such as a pitch, between the first power line M1_R1 and the second power line M1_R2.

The single height cell SHC constitute a single logic cell. In a present specification, the logic cell is a logic device, such as AND, OR, XOR, XNOR, inverter, etc., that executes a specific function. For example, the logic cell include transistors of the logic device and interconnection lines that connect the transistors to each other.

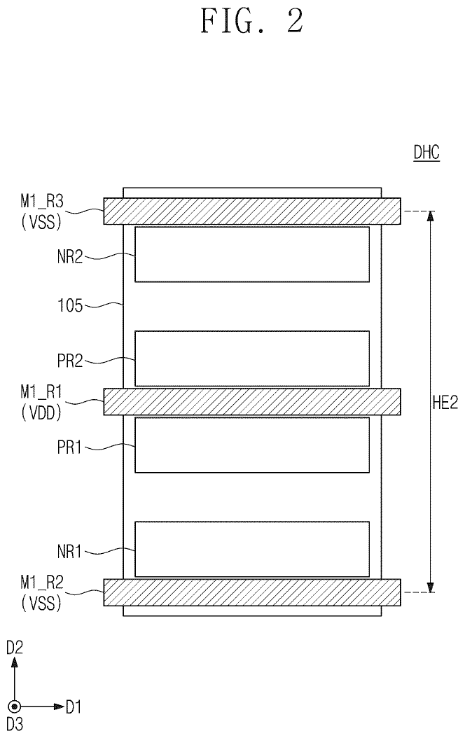

Referring to FIG. 2, in an embodiment, a double height cell DHC is provided. For example, the first power line M1_R1, the second power line M1_R2, and a third power line M1_R3 are disposed on the substrate 105. The first power line M1_R1 is disposed between the second power line M1_R2 and the third power line M1_R3. The third power line M1_R3 is a conduction path to which the drain voltage VDD is provided.

The double height cell DHC is disposed between the second power line M1_R2 and the third power line M1_R3. The double height cell DHC includes a first PMOSFET region PR1, a second PMOSFET region PR2, a first NMOSFET region NR1, and a second NMOSFET region NR2.

The first NMOSFET region NR1 is adjacent to the second power line M1_R2. The second NMOSFET region NR2 is adjacent to the third power line M1_R3. The first and second PMOSFET regions PR1 and PR2 are adjacent to the first power line M1_R1. When viewed in a plan view, the first power line M1_R1 is disposed between the first and second PMOSFET regions PR1 and PR2.

A length of the double height cell DHC in the second direction D2 may be defined as a second height HE2. The second height HE2 is about two times the first height HE1 of FIG. 1. The first and second PMOSFET regions PR1 and PR2 of the double height cell DHC can be combined to serve as a single PMOSFET region.

Thus, a channel size of the PMOS transistor of the double height cell DHC is larger than a channel size of the PMOS transistor of the single height cell SHC of FIG. 1. For example, the channel size of the PMOS transistor of the double height cell DHC is about two times the channel size of the PMOS transistor of the single height cell SHC. For example, the double height cell DHC can be operated at a higher speed than the single height cell SHC. In an embodiment, the double height cell DHC shown in FIG. 2 may be defined as a multi-height cell. In addition, the multi-height cell may include a triple height cell whose cell height is about three times that of the single height cell SHC.

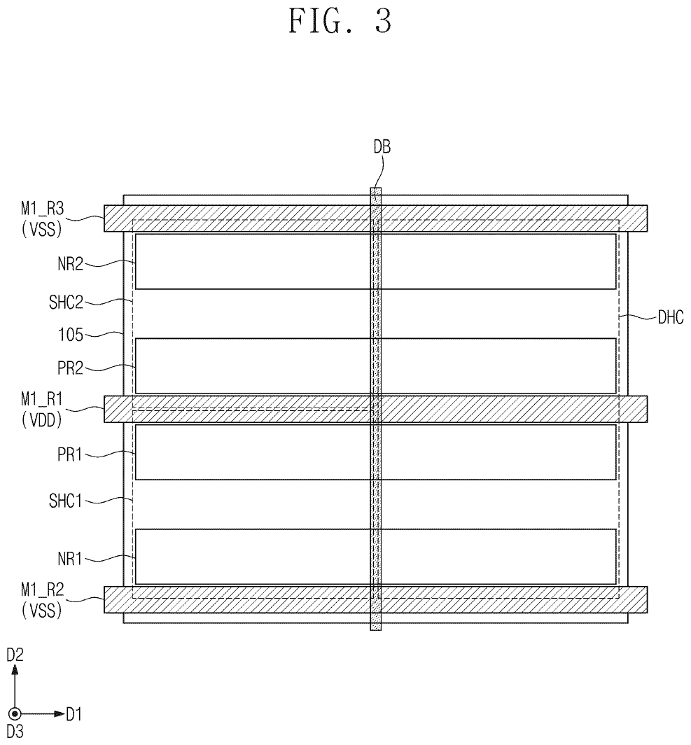

Referring to FIG. 3, in an embodiment, a first single height cell SHC1, a second single height cell SHC2, and a double height cell DHC are two-dimensionally arranged on the substrate 105. The first single height cell SHC1 is disposed between the first and second power lines M1_R1 and M1_R2. The second single height cell SHC2 is disposed between the first and third power lines M1_R1 and M1_R3. The second single height cell SHC2 is adjacent to the first single height cell SHC1 in the second direction D2.

The double height cell DHC is disposed between the second and third power lines M1_R2 and M1_R3. The double height cell DHC is adjacent to the first and second single height cells SHC1 and SHC2 in a first direction D1 that crosses the second direction D1. A division structure DB is disposed between the first single height cell SHC1 and the double height cell DHC and between the second single height cell SHC2 and the double height cell DHC. The division structure DB extends in the second direction D2. An active region of the double height cell DHC is electrically separated from an active region of each of the first and second single height cells SHC1 and SHC2 by the division structure DB.

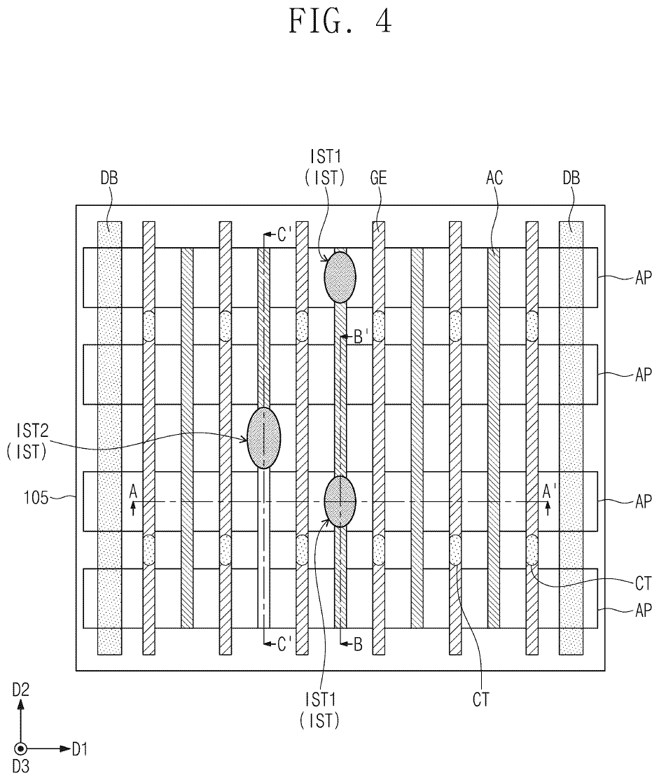

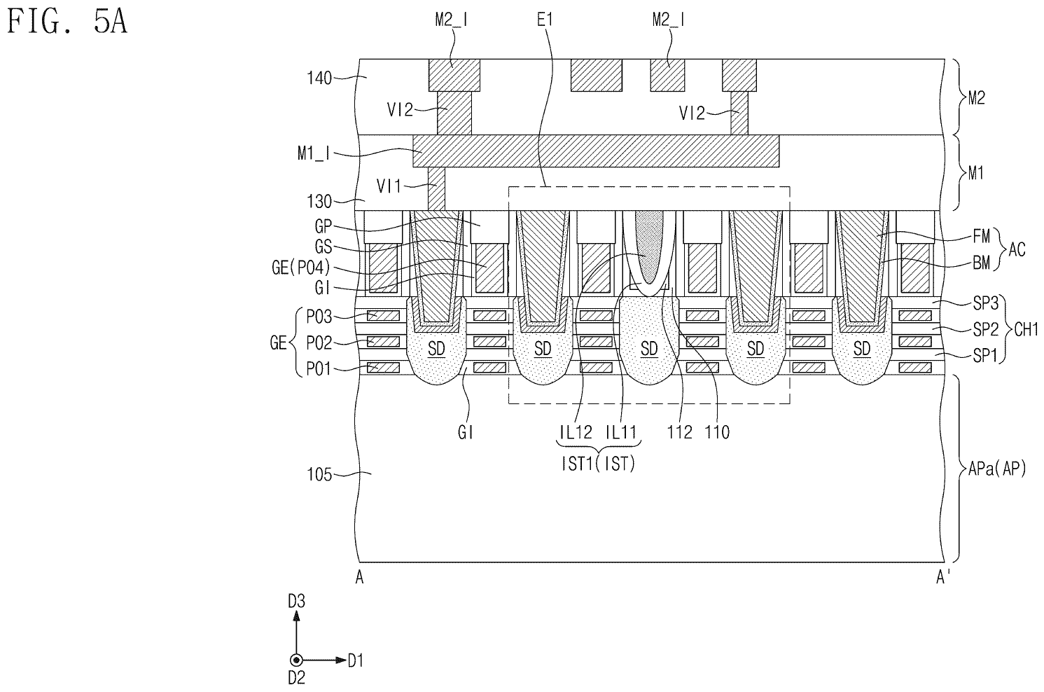

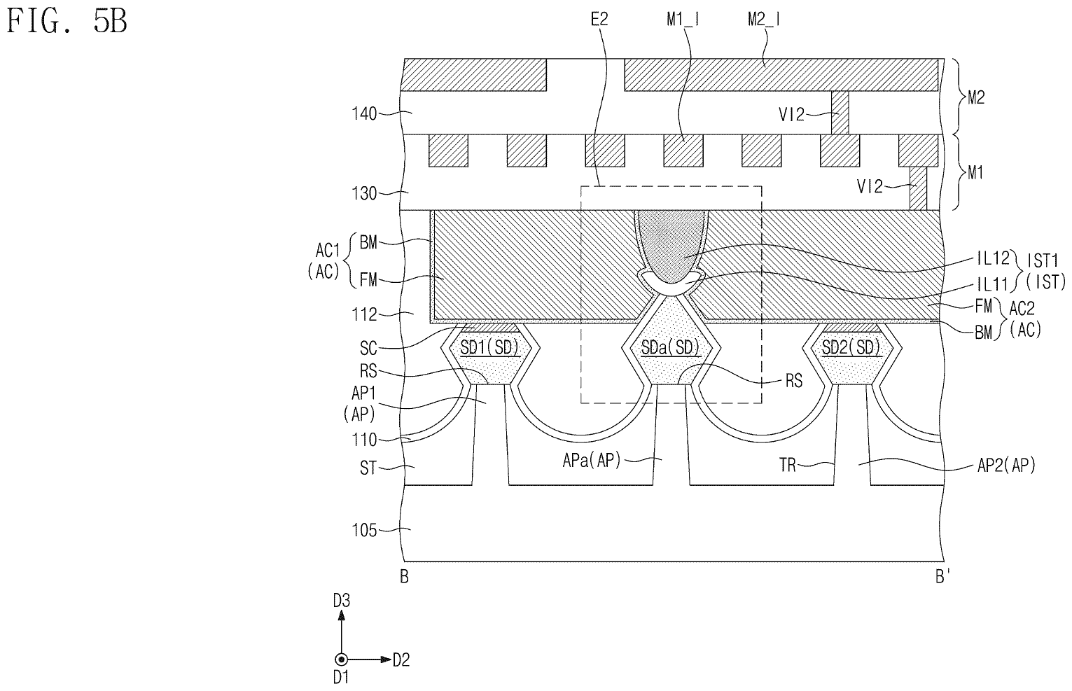

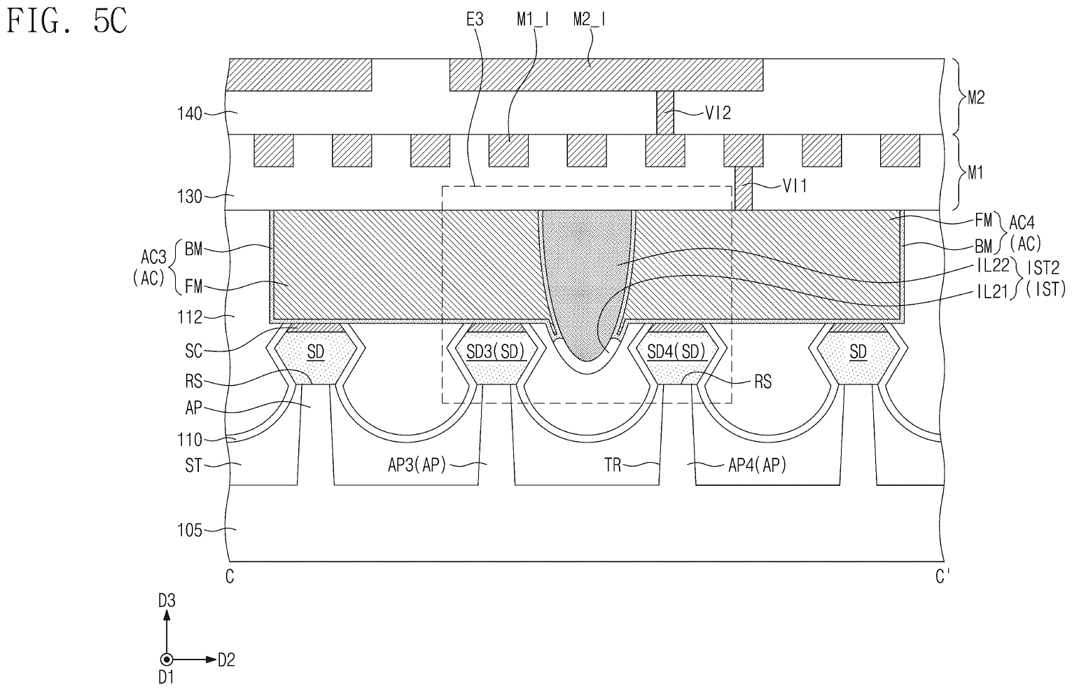

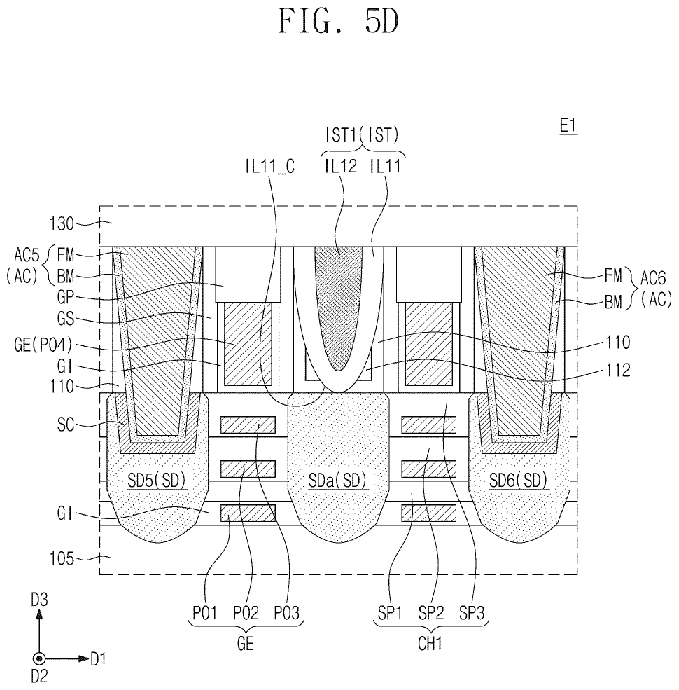

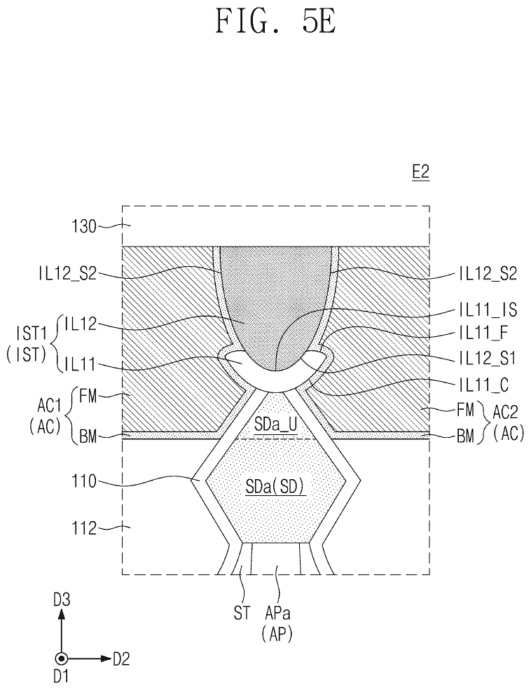

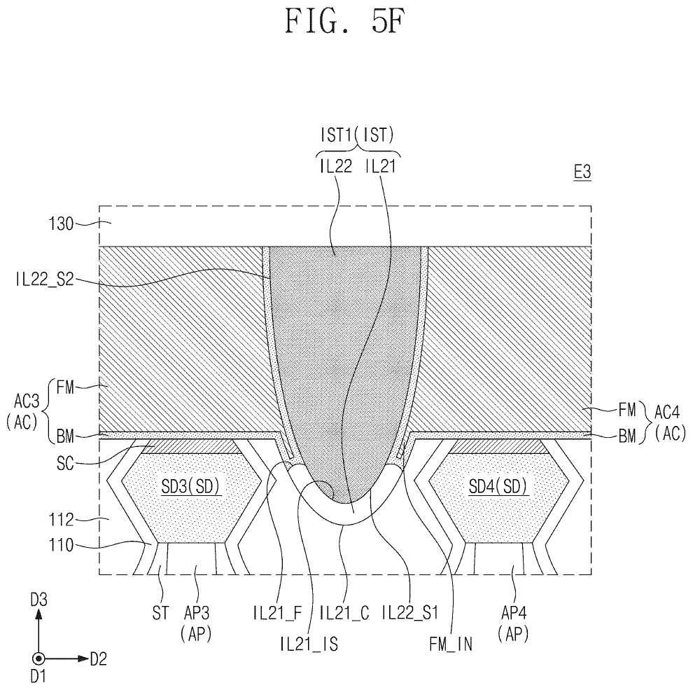

FIG. 4 is a plan view of a semiconductor device according to an embodiment of the inventive concept. FIG. 5A is a cross-sectional view taken along a line A-A′ of FIG. 4. FIG. 5B is a cross-sectional view taken along a line B-B′ of FIG. 4. FIG. 5C is a cross-sectional view taken along a line C-C′ of FIG. 4. FIG. 5D is an enlarged cross-sectional view illustrating a portion E1 of FIG. 5A. FIG. 5E is an enlarged cross-sectional view illustrating a portion E2 of FIG. 5B. FIG. 5F is an enlarged cross-sectional view illustrating a portion E3 of FIG. 5C.

Referring to FIGS. 4 and 5A to 5F, in an embodiment, the semiconductor device includes the substrate 105. In an embodiment, the substrate 105 is a semiconductor substrate. The substrate 105 is formed of or includes at least one of silicon, germanium, silicon-germanium, GaP, or GaAs. In an embodiment, the substrate 105 is one of a silicon-on-insulator (SOI) substrate or a germanium-on-insulator (GOI) substrate. The substrate 105 has a plate-shaped structure that extends in the first and second directions D1 and D2. The first and second directions D1 and D2 are not parallel to each other. For example, the first and second directions D1 and D2 are horizontal directions that are orthogonal to each other.

The substrate 105 includes an active pattern AP. The active pattern AP may be defined by a trench TR formed in an upper portion of the substrate 105. The active pattern AP extends in the first direction D1. The active pattern AP a portion of the substrate 105 that vertically protrudes in a third direction D3. The third direction D3 is not parallel to the first and second directions D1 and D2. For example, the third direction D3 is a vertical direction that is orthogonal to the first and second directions DI and D2.

A device isolation layer ST is disposed on the substrate 105. The device isolation layer ST fills the trench TR. The device isolation layer ST includes an insulating material. For example, the device isolation layer ST is formed of or includes at least one oxide material. The device isolation layer ST does not cover a channel pattern CH1, which will be described below.

The channel patterns CH1 are disposed on the active pattern AP. Each of the channel patterns CH1 includes a first semiconductor pattern SP1, a second semiconductor pattern SP2, and a third semiconductor pattern SP3 that are sequentially arranged in the third direction D3. The first to third semiconductor patterns SP1, SP2, and SP3 are spaced apart from each other in the third direction D3.

In an embodiment, the first to third semiconductor patterns SP1, SP2, and SP3 are formed of or include silicon (Si). For example, each of the first to third semiconductor patterns SP1, SP2, and SP3 is formed of or includes crystalline silicon. In an embodiment, the first to third semiconductor patterns SP1, SP2, and SP3 are formed of or include silicon-germanium (SiGe).

Source/drain patterns SD are disposed on the active pattern AP. A plurality of recesses RS are formed on the active pattern AP. The source/drain patterns SD are disposed in the recesses RS. The channel pattern CH1 are interposed between the source/drain patterns SD that are adjacent to each other in the first direction D1. For example, the first to third semiconductor patterns SP1, SP2, and SP3 connect adjacent source/drain patterns SD to each other.

The source/drain patterns SD are epitaxial patterns formed by a selective epitaxial growth (SEG) process. In an embodiment, a top surface of each of the source/drain patterns SD is located at substantially the same level as a top surface of the third semiconductor pattern SP3. In an embodiment, a top surface of at least one of the source/drain patterns SD is higher than the top surface of the third semiconductor pattern SP3.

Gate electrodes GE that extend in the second direction D2 are disposed on and cross the channel patterns CH1. The gate electrodes GE are arranged at a first pitch in the first direction D1. Each of the gate electrodes GE overlaps the first to third semiconductor patterns SP1, SP2, and SP3 of the channel pattern CH1 in the third direction D3.

The gate electrode GE includes a first inner electrode PO1 interposed between the active pattern AP and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3. The gate electrode GE includes a conductive material.

The gate electrode GE and the first to third semiconductor patterns SP1, SP2, and SP3, which are three-dimensionally enclosed by the gate electrode GE, constitute a three-dimensional field effect transistor, such as a multi-bridge channel FET (MBCFET) or a gate-all-around FET (GAAFET).

A pair of gate spacers GS are respectively disposed on opposite side surfaces of the outer electrode PO4 of the gate electrode GE. The gate spacers GS extend along the gate electrode GE and in the second direction D2. Top surfaces of the gate spacers GS are higher than a top surface of the gate electrode GE. The top surfaces of the gate spacers GS are coplanar with a top surface of a first interlayer insulating layer 110, which will be described below. The gate spacer GS includes an insulating material. For example, the gate spacer GS is formed of or includes at least one nitride material.

A gate capping pattern GP is disposed on the gate electrode GE. The gate capping pattern GP extends along the gate electrode GE and in the second direction D2. The gate capping pattern GP includes a material that has an etch selectivity with respect to first and second interlayer insulating layers 110 and 112, which will be described below. For example, the gate capping pattern GP is formed of or includes at least one nitride material.

Gate insulating layers GI are provided. The gate insulating layer GI separates the gate electrode GE from the channel pattern CH1. The gate insulating layer GI is interposed between the gate electrode GE and the channel pattern CH1. The gate insulating layer GI three-dimensionally encloses the first to third semiconductor patterns SP1, SP2, and SP3. The gate insulating layer GI covers the device isolation layer ST. The gate insulating layer GI includes an insulating material. For example, the gate insulating layer GI is formed of or includes at least one oxide material.

A first interlayer insulating layer 110 covers the gate spacers GS and the source/drain patterns SD. The first interlayer insulating layer 110 conformally covers the gate spacers GS and the source/drain patterns SD. A second interlayer insulating layer 112 is disposed on the first interlayer insulating layer 110. A top surface of the second interlayer insulating layer 112 is coplanar with a top surface of the gate capping pattern GP, a top surface of the gate spacer GS, and a top surface of an active contact AC. A third interlayer insulating layer 130 is disposed on the second interlayer insulating layer 112. A fourth interlayer insulating layer 140 is disposed on the third interlayer insulating layer 130. Each of the first to fourth interlayer insulating layers 110, 112, 130, and 140 includes an insulating material. For example, the first interlayer insulating layer 110 is formed of or includes at least one nitride material, and the second to fourth interlayer insulating layers 112, 130, and 140 are formed of or include at least one oxide material.

The division structures DB are provided. The division structure DB extends in the second direction D2. The gate electrodes GE are disposed between the division structures DB. A pitch between the division structure DB and the gate electrode GE adjacent thereto is equal to the first pitch.

Gate cutting patterns CT are provided. The gate cutting patterns CT separate the gate electrodes GE from each other in the second direction D2. The gate cutting patterns CT is formed of or includes at least one insulating material, such as silicon oxide, silicon nitride, or combinations thereof.

The active contacts AC penetrate the first and second interlayer insulating layers 110 and 112 and are electrically connected to the source/drain patterns SD. The active contact AC is a self-aligned contact. For example, the active contact AC is formed by a self-alignment process that uses the gate capping pattern GP and the gate spacer GS. The active contact AC covers at least a portion of the side surface of the gate spacer GS.

Metal-semiconductor compound layers SC are provided. The metal-semiconductor compound layer SC are interposed between the active contact AC and the source/drain pattern SD. The metal-semiconductor compound layer SC lower a contact resistance between the active contact AC and the source/drain pattern SD. The active contact AC is electrically connected to the source/drain pattern SD through the metal-semiconductor compound layer SC. The metal-semiconductor compound layer SC is formed of or includes at least one of titanium-silicide, tantalum-silicide, tungsten-silicide, nickel-silicide, or cobalt-silicide.

The active contact AC includes a conductive pattern FM and a barrier layer BM that encloses the conductive pattern FM. For example, the conductive pattern FM is formed of or includes at least one of aluminum, copper, tungsten, molybdenum, or cobalt. The barrier layer BM covers side and bottom surfaces of the conductive pattern FM. The barrier layer BM includes at least one of a metal layer or a metal nitride layer. The metal layer is formed of or includes at least one of titanium, tantalum, tungsten, nickel, cobalt, or platinum. The metal nitride layer is formed of or includes at least one of titanium nitride (TiN), tantalum nitride (TaN), tungsten nitride (WN), nickel nitride (NiN), cobalt nitride (CoN), or platinum nitride (PtN).

An insulating structure IST is provided. The insulating structure IST is disposed between the active contacts AC that are adjacent to each other in the first direction D1. The insulating structure IST is disposed between the active contacts AC that are adjacent to each other in the second direction D2. The insulating structure IST is in contact with the active contacts AC that are adjacent to each other in the second direction D2. The top surface of the active contact AC, the top surface of the gate spacer GS, the top surface of the gate capping pattern GP, the top surface of the second interlayer insulating layer 112, and the top surface of the insulating structure IST are substantially coplanar with each other.

The insulating structure IST includes first insulating layers IL11 and IL21 and second insulating layers IL12 and IL22 disposed on the first insulating layers IL11 and IL21, respectively. The first insulating layers IL11 and IL21 of the insulating structure IST have an etch selectivity with respect to the second insulating layers IL12 and IL22 of the insulating structure IST. For example, the first insulating layers IL11 and IL21 of the insulating structure IST are etched faster by an etchant material as compared with the second insulating layers IL12 and IL22 of the insulating structure IST.

The first insulating layers IL11 and IL21 of the insulating structure IST and the second insulating layers IL12 and IL22 of the insulating structure IST include insulating materials. For example, the first insulating layers IL11 and IL21 of the insulating structure IST are formed of or include at least one oxide material, and the second insulating layers IL12 and IL22 of the insulating structure IST are formed of or include at least one nitride material. In an embodiment, the first insulating layers IL11 and IL21 and the second insulating layers IL12 and IL22 of the insulating structure IST are formed of or include SiOC or SiOCN.

A first metal layer M1 is disposed in the third interlayer insulating layer 130. For example, the first metal layer M1 includes a first power line M1_R1, a second power line M1_R2, and first interconnection lines M1_I. The interconnection lines M1_R1, M1_R2, and M1_I of the first metal layer M1 extend in the first direction D1 parallel to each other.

The first interconnection lines M1_I of the first metal layer M1 is disposed between the first and second power lines M1_R1 and M1_R2. The first interconnection lines M1_I of the first metal layer Ml are arranged at a second pitch in the second direction D2. The second pitch is smaller than the first pitch. A linewidth of each of the first interconnection lines M1_I is smaller than a linewidth of each of the first and second power lines M1_R1 and M1_R2.

The first metal layer M1 further includes first vias VI1. The first vias VI1 are disposed below the interconnection lines M1_R1, M1_R2, and M1_I of the first metal layer M1. The active contact AC and the interconnection line of the first metal layer M1 are electrically connected to each other through the first via VI1. A gate contact GC and the interconnection line of the first metal layer M1 are electrically connected to each other through the first via VI1.

The interconnection line of the first metal layer M1 and the first via VI1 thereunder are formed by separate processes. For example, the interconnection line and the first via VI1 of the first metal layer M1 are independently formed by respective single damascene processes.

A second metal layer M2 is disposed in the fourth interlayer insulating layer 140. The second metal layer M2 includes a plurality of second interconnection lines M2_I. Each of the second interconnection lines M2_I of the second metal layer M2 has a line-or bar-shaped pattern that extends in the second direction D2. For example, the second interconnection lines M2_I extend in the second direction D2 parallel to each other.

The second metal layer M2 further includes second vias VI2 disposed below the second interconnection lines M2_I. The interconnection lines of the first and second metal layers M1 and M2 are electrically connected to each other through the second via VI2. The interconnection line of the second metal layer M2 and the second via VI2 thereunder are formed together by a dual damascene process.

The interconnection lines of the first metal layer M1 are formed of or include a conductive material that is the same as or different from those of the second metal layer M2. For example, the interconnection lines of the first and second metal layers M1 and M2 are formed of or include at least one metal, such as aluminum, copper, tungsten, ruthenium, molybdenum, or cobalt. In addition, a plurality of metal layers, such as M3, M4, M5, etc., may be additionally stacked on the fourth interlayer insulating layer 140. Each of the stacked metal layers includes interconnection lines used as routing paths between cells.

The insulating structure IST includes a plurality of insulating structures IST1 and IST2. The insulating structures IST1 and IST2 include a first insulating structure IST1 and a second insulating structure IST2.

Referring back to FIG. 4, in an embodiment, the active contacts AC are spaced apart from each other in the first direction D1. Each of the active contacts AC extends along the second direction D2. The active contacts AC are disposed between the gate electrodes GE that are adjacent to each other in the first direction D1. The active contacts AC and the gate electrodes GE are alternately arranged between the division structures DB. When viewed in a plan view, the active contact AC and the gate electrode GE are bar-shaped patterns that extend in the second direction D2.

The first and second insulating structures IST1 and IST2 are disposed between the gate electrodes GE that are adjacent to each other in the first direction D1, when viewed in a plan view.

The active pattern AP includes a plurality of active patterns AP1, AP2, AP3, AP4, and APa. The active patterns AP1, AP2, AP3, AP4, and APa include a first active pattern AP1, a second active pattern AP2, a third active pattern AP3, a fourth active pattern AP4, and an intervening active pattern APa. The first and second active patterns AP1 and AP2 are spaced apart from each other in the second direction D2 with the intervening active pattern APa interposed therebetween. The first insulating structure IST1 is disposed between the first and second active patterns AP1 and AP2. The third and fourth active patterns AP3 and AP4 are spaced apart from each other in the second direction D2, with the second insulating structure IST2 interposed therebetween.

The source/drain patterns SD include a first source/drain pattern SD1 on the first active pattern AP1, a second source/drain pattern SD2 on the second active pattern AP2, a third source/drain pattern SD3 on the third active pattern AP3, a fourth source/drain pattern SD4 on the fourth active pattern AP4, a fifth source/drain pattern SD5 on the intervening active pattern APa, a sixth source/drain pattern SD6 on the intervening active pattern APa, and an intervening source/drain pattern SDa on the intervening active pattern APa. The first and second source/drain patterns SD1 and SD2 are adjacent to the intervening source/drain pattern SDa in the second direction D2. The intervening source/drain pattern SDa are disposed between the first and second source/drain patterns SD1 and SD2. The third and fourth source/drain patterns SD3 and SD4 are adjacent to each other in the second direction D2. The fifth and sixth source/drain patterns SD5 and SD6 are adjacent to the intervening source/drain pattern SDa in the first direction D1. The intervening source/drain pattern SDa is disposed between the fifth and sixth source/drain patterns SD5 and SD6.

The inner electrodes PO1, PO2, and PO3 are disposed between the fifth source/drain pattern SD5 and the intervening source/drain pattern SDa, and between the sixth source/drain pattern SD6 and the intervening source/drain pattern SDa. The semiconductor patterns SP1, SP2, and SP3 are disposed between the fifth source/drain pattern SD5 and the intervening source/drain pattern SDa, and between the sixth source/drain pattern SD6 and the intervening source/drain pattern SDa.

The active contacts AC include a first active contact AC1 disposed on the first source/drain pattern SD1, a second active contact AC2 disposed on the second source/drain pattern SD2, a third active contact AC3 disposed on the third source/drain pattern SD3, a fourth active contact AC4 disposed on the fourth source/drain pattern SD4, a fifth active contact AC5 disposed on the fifth source/drain pattern SD5, and a sixth active contact AC6 disposed on the sixth source/drain pattern SD6. The first and second active contacts AC1 and AC2 are spaced apart from each other in the second direction D2, with the first insulating structure IST1 interposed therebetween. The fifth and sixth active contacts AC5 and AC6 are spaced apart from each other in the first direction D1, with the first insulating structure IST1 interposed therebetween. The third and fourth active contacts AC3 and AC4 are spaced apart from each other in the second direction D2, with the second insulating structure IST2 interposed therebetween. The intervening source/drain pattern SDa are spaced apart from the active contact AC.

The first active contact AC1 is electrically connected to the first source/drain pattern SD1. The second active contact AC2 is electrically connected to the second source/drain pattern SD2. The third active contact AC3 is electrically connected to the third source/drain pattern SD3. The fourth active contact AC4 is electrically connected to the fourth source/drain pattern SD4. The fifth active contact AC5 is electrically connected to the fifth source/drain pattern SD5. The sixth active contact AC6 is electrically connected to the sixth source/drain pattern SD6.

Referring back to FIGS. 5D and 5E, in an embodiment, the first insulating structure IST1 is in contact with the first and second active contacts AC1 and AC2. The first insulating structure IST1 overlaps the intervening source/drain pattern SDa. The first insulating structure IST1 is in contact with the intervening source/drain pattern SDa.

The outer electrode PO4 is disposed between the first insulating structure IST1 and the fifth active contact AC5 and between the first insulating structure IST1 and the sixth active contact AC6. The first and second interlayer insulating layers 110 and 112 are disposed between the intervening source/drain pattern SDa, the first insulating structure IST1, and the gate spacer GS. The second interlayer insulating layer 112 is interposed between the first insulating structure IST1 and the first interlayer insulating layer 110. The intervening source/drain pattern SDa is in contact with the first interlayer insulating layer 110. The first insulating structure IST1 is in contact with the first and second interlayer insulating layers 110 and 112.

The first insulating structure IST1 includes the first insulating layer IL11 and the second insulating layer IL12 disposed on the first insulating layer IL11. The first insulating layer IL11 encloses at least a portion of the second insulating layer IL12. The first insulating layer IL11 and the second insulating layer IL12 are in contact with the first and second active contacts AC1 and AC2. The first insulating layer IL11 is in contact with the intervening source/drain pattern SDa and the first interlayer insulating layer 110.

The first insulating layer IL11 of the first insulating structure IST1 includes an inner surface IL11_IS, a curved surface IL11_C, and a connection surface IL11_F. The inner surface IL11_IS of the first insulating layer IL11 is in contact with the second insulating layer IL12. The curved surface IL11_C of the first insulating layer IL11 is in contact with the intervening source/drain pattern SDa, the first interlayer insulating layer 110, the second interlayer insulating layer 112, the barrier layer BM of the first active contact AC1, and the barrier layer BM of the second active contact AC2. The curved surface IL11_C of the first insulating layer IL11 has a curved shape. The curved surface IL11_C of the first insulating layer IL11 is convex toward the intervening source/drain pattern SDa. The connection surface IL11_F of the first insulating layer IL11 connects the inner surface IL11_IS to the curved surface IL11_C. The connection surface IL11_F of the first insulating layer IL11 is in contact with the barrier layer BM of the first active contact AC1 and the barrier layer BM of the second active contact AC2.

The second insulating layer IL12 of the first insulating structure IST1 includes a first surface IL12_S1 and a second surface IL12_S2. The first surface IL12_S1 of the second insulating layer IL12 is in contact with the inner surface IL11_IS of the first insulating layer IL11. The second surface IL12_S2 of the second insulating layer IL12 is in contact with the barrier layer BM of the first active contact AC1 and the barrier layer BM of the second active contact AC2.

The intervening source/drain pattern SDa are spaced apart from the first and second active contacts AC1 and AC2. The intervening source/drain pattern SDa includes an upper portion SDa_U between the first and second active contacts AC1 and AC2. The upper portion SDa_U of the intervening source/drain pattern SDa is in contact with the curved surface IL11_C of the first insulating layer IL11. The first interlayer insulating layer 110 is interposed between the upper portion SDa_U of the intervening source/drain pattern SDa and the first active contact AC1 and between the upper portion SDa_U of the intervening source/drain pattern SDa and the second active contact AC2. The upper portion SDa_U of the intervening source/drain pattern SDa is located at the same level as a portion of the active contact AC.

A level of the lowermost portion of the first insulating layer IL11 of the first insulating structure IST1 is higher than a level of the lowermost portion of the active contact AC. A level of the connection surface IL11_F of the first insulating layer IL11 is lower than a level of the top surface of the active contact AC. The level of the connection surface IL11_F of the first insulating layer IL11 is higher than the level of the lowermost portion of the active contact AC. The level of the connection surface IL11_F of the first insulating layer IL11 is higher than a level of the lowermost portion of the second insulating layer IL12.

A level of the first surface IL12_S1 of the second insulating layer IL12 of the first insulating structure IST1 is higher than a level of the source/drain pattern SD. The level of the first surface IL12_S1 of the second insulating layer IL12 is lower than the level of the top surface of the active contact AC and higher than a level of a bottom surface of the active contact AC.

As a vertical level is lowered, a width of the second insulating layer IL12 of the first insulating structure IST1 decreases. The width of the second insulating layer IL12 of the first insulating structure IST1 is less than the greatest width of the intervening source/drain pattern SDa. In an embodiment, the width of the second insulating layer IL12 of the first insulating structure IST1 is greater than the width of the intervening source/drain pattern SDa.

Referring back to FIG. 5F, in an embodiment, the second insulating structure IST2 is in contact with the third and fourth active contacts AC3 and AC4. The second insulating structure IST2 is disposed between the third and fourth source/drain patterns SD3 and SD4. The second insulating structure IST2 is spaced apart from the source/drain pattern SD.

The second insulating structure IST2 includes the first insulating layer IL21 and the second insulating layer IL22 disposed on the first insulating layer IL21. The first insulating layer IL21 encloses at least a portion of the second insulating layer IL22. The first insulating layer IL21 and the second insulating layer IL22 are in contact with the third and fourth active contacts AC3 and AC4. The first insulating layer IL21 is disposed on the second interlayer insulating layer 112. The first insulating layer IL21 is disposed between the third and fourth source/drain patterns SD3 and SD4.

The first insulating layer IL21 of the second insulating structure IST2 includes an inner surface IL21_IS, a curved surface IL21_C, and a connection surface IL21_F. The inner surface IL21_IS of the first insulating layer IL21 is in contact with the second insulating layer IL22. The curved surface IL21_C of the first insulating layer IL21 is in contact with the second interlayer insulating layer 112. The curved surface IL21_C of the first insulating layer IL21 is spaced apart from the active contact AC. The curved surface IL21_C of the first insulating layer IL21 has a curved shape. The curved surface IL11_C of the first insulating layer IL11 is convex toward the substrate 105. The connection surface IL11_F of the first insulating layer IL21 connects the inner surface IL21_IS to the curved surface IL21_C. The connection surface IL21_F of the first insulating layer IL21 is in contact with the barrier layer BM of the third active contact AC3 and the barrier layer BM of the fourth active contact AC4.

The second insulating layer IL22 of the second insulating structure IST2 includes a first surface IL22_S1 and a second surface IL22_S2. The first surface IL22_S1 of the second insulating layer IL22 is in contact with the inner surface IL21_IS of the first insulating layer IL21. The second surface IL22_S2 of the second insulating layer IL22 is in contact with the barrier layer BM of the third active contact AC3 and the barrier layer BM of the fourth active contact AC4.

The conductive pattern FM of each of the third and fourth active contacts AC3 and AC4 includes an intervening portion FM_IN. The intervening portion FM_IN of the conductive pattern FM of each of the third and fourth active contacts AC3 and AC4 protrudes toward the first insulating layer IL21 of the second insulating structure IST2. The barrier layer BM of the third active contact AC3 is interposed between the intervening portion FM_IN of the conductive pattern FM of the third active contact AC3 and the connection surface IL21_F of the first insulating layer IL21. The intervening portion FM_IN of the conductive pattern FM of the third active contact AC3 is disposed between the second insulating layer IL22 of the second insulating structure IST2 and the third source/drain pattern SD3. The barrier layer BM of the fourth active contact AC4 is interposed between the intervening portion FM_IN of the conductive pattern FM of the fourth active contact AC4 and the connection surface IL21_F of the first insulating layer IL21. The intervening portion FM_IN of the conductive pattern FM of the fourth active contact AC4 is disposed between the second insulating layer IL22 of the second insulating structure IST2 and the fourth source/drain pattern SD4.

A level of the lowermost portion of the first insulating layer IL21 of the second insulating structure IST2 is lower than a level of the lowermost portion of the active contact AC. The level of the connection surface IL21_F of the first insulating layer IL21 is lower than the level of the top surface of the active contact AC. The level of the connection surface IL21_F of the first insulating layer IL21 is lower than a level of the uppermost portion of the source/drain pattern SD and is higher than a level of the lowermost portion of the source/drain pattern SD. The level of the connection surface IL21_F of the first insulating layer IL21 is higher than a level of the lowermost portion of the second insulating layer IL22. The first insulating layer IL21 is disposed at the same level as the third and fourth source/drain patterns SD3 and SD4.

A level of the first surface IL22_S1 of the second insulating layer IL22 of the second insulating structure IST2 is lower than a level of the active contact AC. The level of the first surface IL22_S1 of the second insulating layer IL22 is lower than the level of the uppermost portion of the source/drain pattern SD and is higher than the level of the lowermost portion of the source/drain pattern SD.

As a vertical level is lowered, a width of the second insulating layer IL22 of the second insulating structure IST2 decreases. As a vertical level is lowered, a distance between the third and fourth active contacts AC3 and AC4 decreases. In an embodiment, the shortest distance between the third and fourth active contacts AC3 and AC4 is about 20 nm.

In a semiconductor device according to an embodiment of the inventive concept, the insulating structures IST1 and IST2 are disposed between adjacent active contacts AC. For example, resistance characteristics between the active contacts AC are improved, and the electrical characteristics of the semiconductor device are improved.

In a semiconductor device according to an embodiment of the inventive concept, the active contact AC includes the intervening portion FM_IN that protrudes toward the insulating structure IST2. For example, the size of the active contact AC is increased, and thus, the resistance characteristics of the active contacts AC and the electrical characteristics of the semiconductor device are improved.

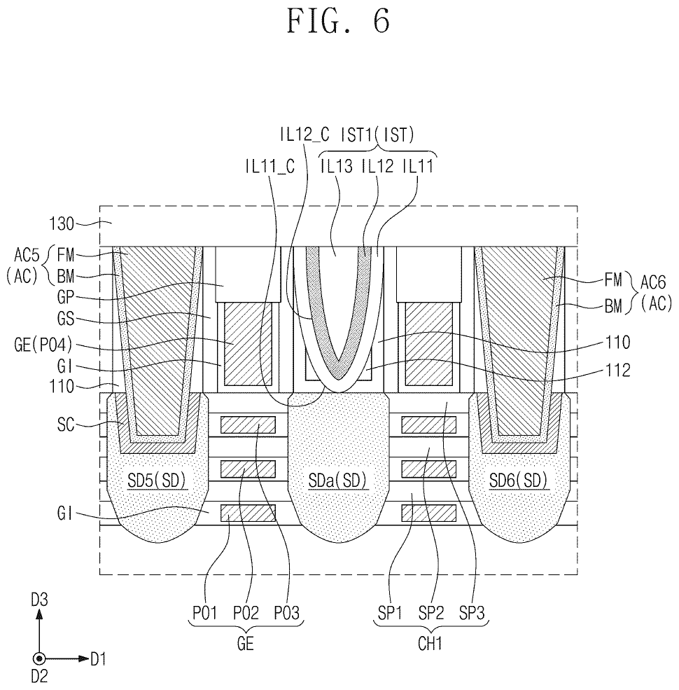

FIG. 6 is an enlarged view of a semiconductor device according to an embodiment of the inventive concept. FIG. 6 is an enlarged view that corresponds to FIG. 5D. A semiconductor device of FIG. 6 is similar to a semiconductor device described with reference to FIGS. 4A to 5F, except for the features to be described below.

Referring to FIG. 6, in an embodiment, the first insulating structure IST1 further includes a third insulating layer IL13. The third insulating layer IL13 is enclosed by the second insulating layer IL12. The second insulating layer IL12 is enclosed by the first insulating layer IL11.

The third insulating layer IL13 includes an insulating material. The number of the insulating layers IL1, IL2, and IL3 is not necessarily limited to that shown in the illustrated example. For example, the number of the insulating layers may be equal to or greater than four.

However, embodiments of the inventive concept are not necessarily limited to the afore-described example, and in other embodiments, the second insulating structure IST2 also includes a plurality of insulating layers.

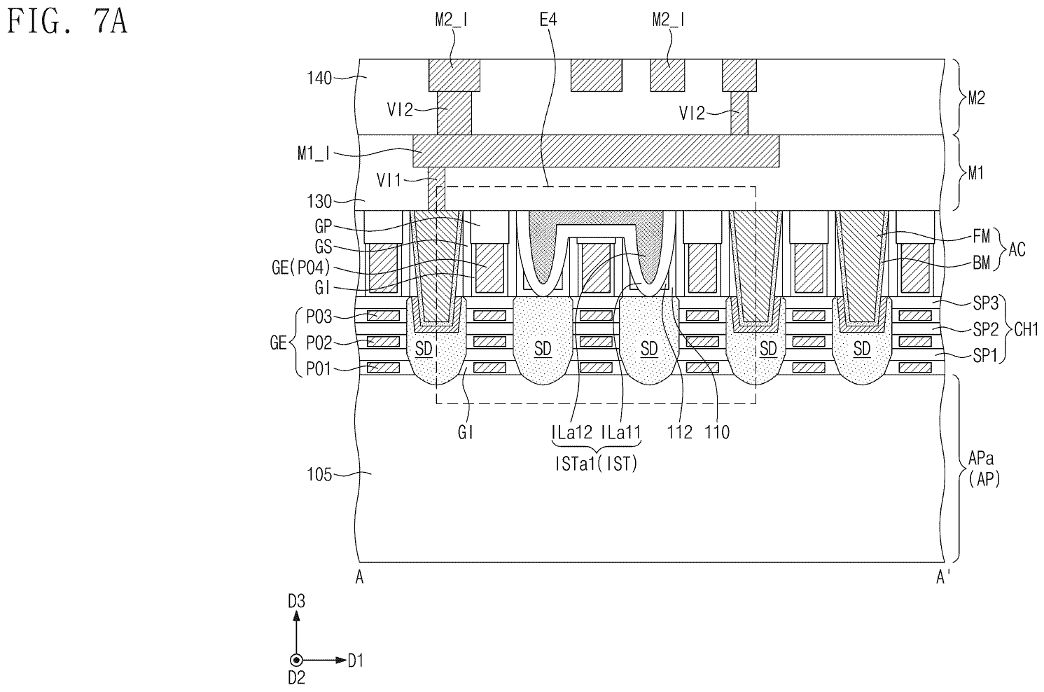

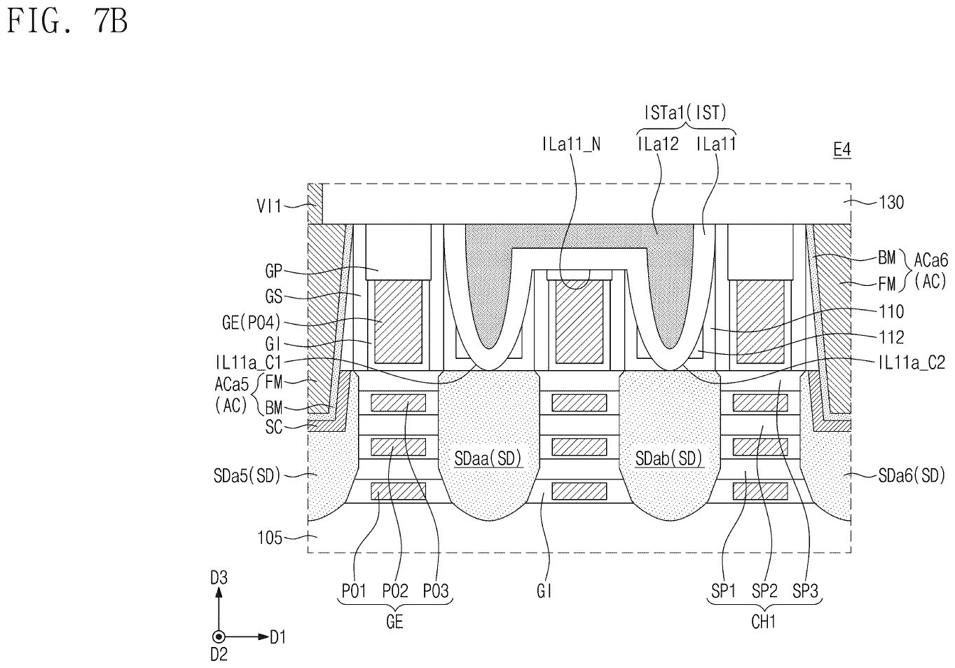

FIG. 7A is a cross-sectional view of a semiconductor device according to an embodiment of the inventive concept. FIG. 7B is an enlarged view of a semiconductor device according to an embodiment of the inventive concept. FIG. 7A is a cross-sectional view that corresponds to FIG. 5A. FIG. 7B is an enlarged view that corresponds to FIG. 5D. A semiconductor device according to FIGS. 7A and 7B is similar to a semiconductor device described with reference to FIGS. 4A to 5F, except for the features to be described below.

Referring to FIGS. 7A and 7B, in an embodiment, a first intervening source/drain pattern SDaa, a second intervening source/drain pattern SDab, a fifth source/drain pattern SDa5, and a sixth source/drain pattern SDa6 are provided. The first and second intervening source/drain patterns SDaa and SDab are adjacent to each other in the first direction D1. The fifth and sixth source/drain patterns SD5 and SD6 are spaced apart from each other in the first direction D1, with the first and second intervening source/drain patterns SDaa and SDab interposed therebetween.

The inner electrodes PO1, PO2, and PO3 are disposed between the first intervening source/drain pattern SDaa and the fifth source/drain pattern SDa5, between the first intervening source/drain pattern SDaa and the second intervening source/drain pattern SDab, and between the second intervening source/drain pattern SDab and the sixth source/drain pattern SDa6. The semiconductor patterns SP1, SP2, and SP3 are disposed between the first intervening source/drain pattern SDaa and the fifth source/drain pattern SDa5, between the first intervening source/drain pattern SDaa and the second intervening source/drain pattern SDab, and between the second intervening source/drain pattern SDab and the sixth source/drain pattern SDa6.

A fifth active contact ACa5 is disposed on the fifth source/drain pattern SDa5, and a sixth active contact ACa6 is disposed on the sixth source/drain pattern SDa6. A first insulating structure ISTa1 is disposed between the fifth and sixth active contacts ACa5 and ACa6. The first insulating structure ISTa1 includes a first insulating layer ILa11 and a second insulating layer ILa12 on the first insulating layer ILa11.

The first insulating layer ILa11 of the first insulating structure ISTa1 includes a first curved surface ILa11_C1, a second curved surface ILa11_C2, and a connection surface ILa11_N. The first curved surface ILa11_C1 of the first insulating layer ILa11 is in contact with the first intervening source/drain pattern SDaa. The second curved surface ILa11_C2 of the first insulating layer ILa11 is in contact with the second intervening source/drain pattern SDab. The connection surface ILa11_N of the first insulating layer ILa11 connects the first and second curved surfaces ILa11_C1 and ILa11_C2 of the first insulating layer ILa11 to each other.

A pair of the gate spacers GS, the outer electrode PO4, and the gate capping pattern GP are disposed between the first and second curved surfaces ILa11_C1 and ILa11_C2. A top surface of each of the gate spacers GS and the gate capping pattern GP between the first and second curved surfaces ILa11_C1 and ILa11_C2 is in contact with the connection surface ILa11_N of the first insulating layer ILa11.

The number of the intervening source/drain patterns SDaa and SDab and the curved surfaces ILa11_C1 and ILa11_C2 of the first insulating layer ILa11 is not necessarily limited to the illustrated example. For example, the number of the intervening source/drain patterns SDaa and SDab and the curved surfaces ILa11_C1 and ILa11_C2 of the first insulating layer ILa11 may be equal to or greater than three.

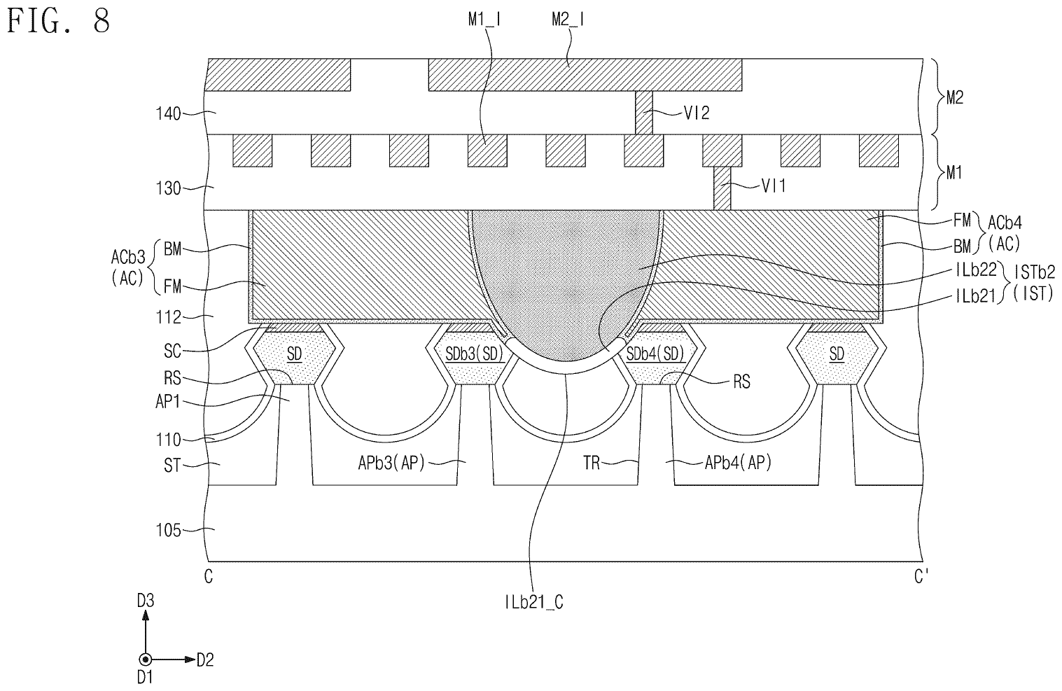

FIG. 8 is a sectional view of a semiconductor device according to an embodiment of the inventive concept. FIG. 8 is a sectional view that corresponds to FIG. 5C. A semiconductor device of FIG. 8 is similar to a semiconductor device described with reference to FIGS. 4 to 5F, except for the features to be described below.

Referring to FIG. 8, in an embodiment, a third active pattern APb3 and a fourth active pattern APb4 may be provided. A third source/drain pattern SDb3 and a fourth source/drain pattern SDb4 are disposed on the third active pattern APb3 and the fourth active pattern APb4, respectively. A third active contact ACb3 is electrically connected to the third source/drain pattern SDb3, and a fourth active contact ACb4 is electrically connected to the fourth source/drain pattern SDb4. A second insulating structure ISTb2 is disposed between the third active contact ACb3 and the fourth active contact ACb4.

The second insulating structure ISTb2 is in contact with the third active contact ACb3 and the fourth active contact ACb4. The second insulating structure ISTb2 includes a first insulating layer ILb21 and a second insulating layer ILb22 disposed on the first insulating layer ILb21.

The first insulating layer ILb21 of the second insulating structure ISTb2 is in contact with the third source/drain pattern SDb3 and the fourth source/drain pattern SDb4. The first insulating layer ILb21 has a curved surface ILb21_C that is in contact with the first interlayer insulating layer 110, the second interlayer insulating layer 112, the third source/drain pattern SDb3, and the fourth source/drain pattern SDb4.

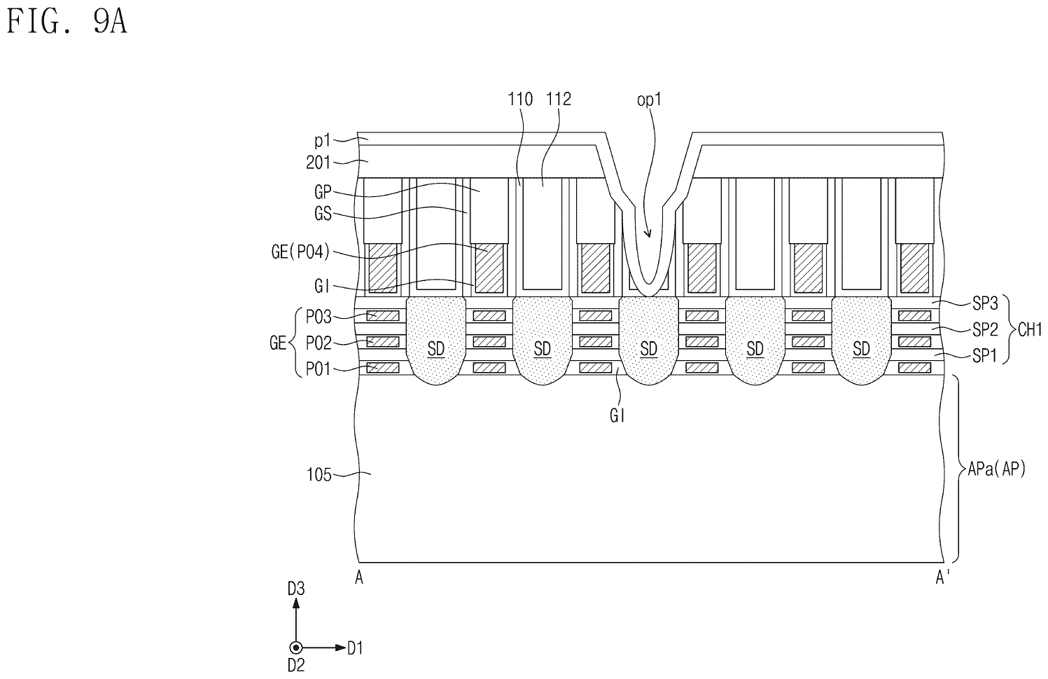

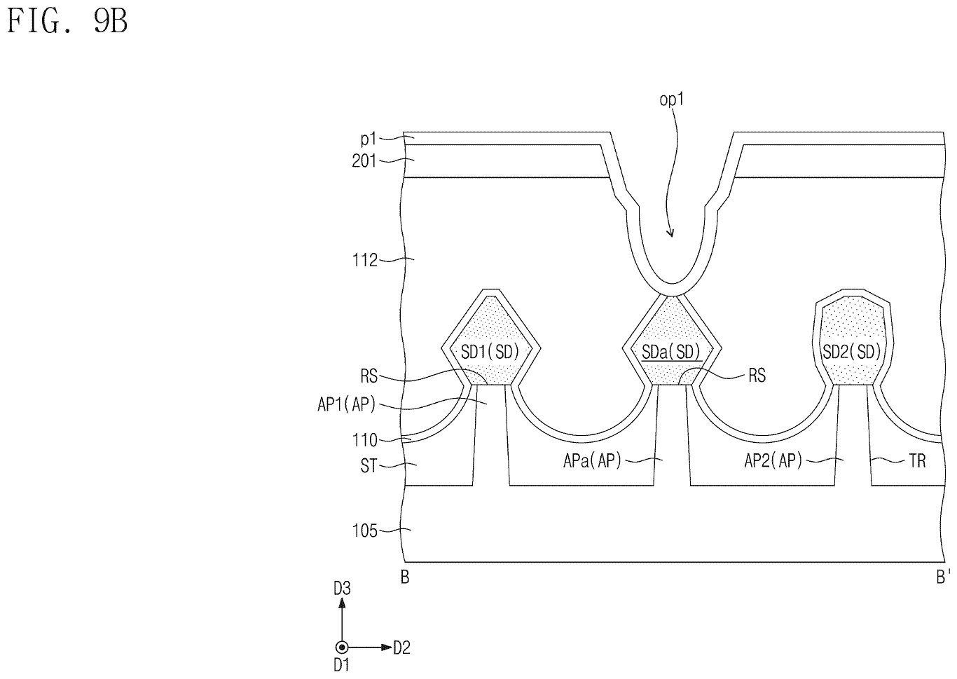

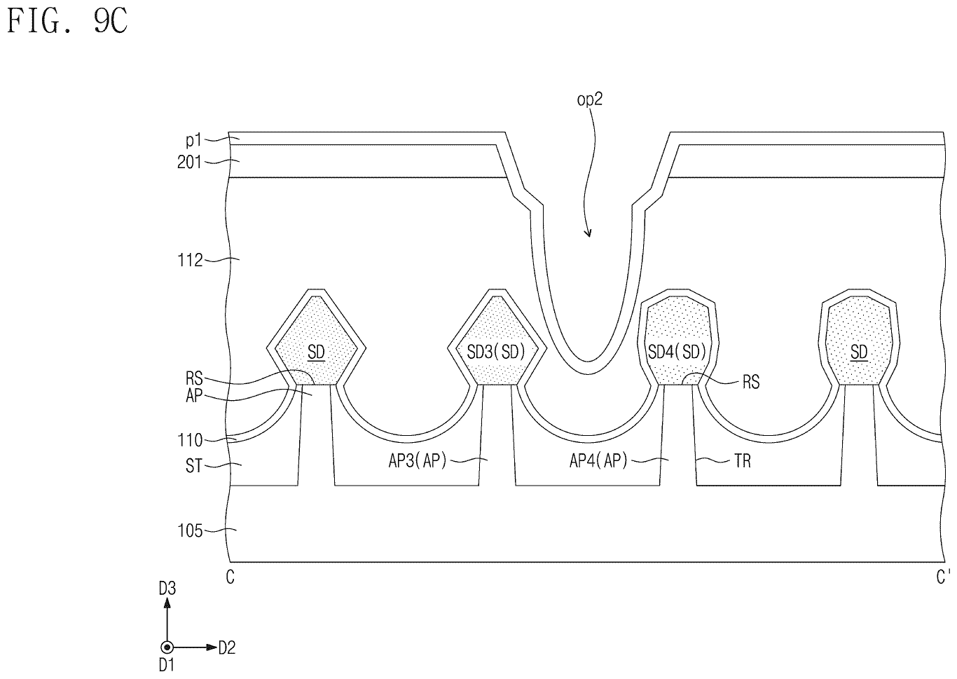

FIGS. 9A, 9B, 9C, 10A, 10B, 10C, 11A, 11B, 11C, 12A, 12B, and 12C are cross-sectional views that illustrate a method of fabricating a semiconductor device, according to an embodiment of the inventive concept. FIGS. 9A, 10A, 11A, and 12A are cross-sectional views that correspond to FIG. 5A. FIGS. 9B, 10B, 11B, and 12B are cross-sectional views that correspond to FIG. 5B. FIGS. 9C, 10C, 11C, and 12C are cross-sectional views that correspond to FIG. 5C.

Referring to FIGS. 9A, 9B, and 9C, in an embodiment, the substrate 105 with the trench TR is formed. The active pattern AP is defined by the trench TR. The device isolation layer ST is formed to fill the trench TR. The gate spacers GS are formed. The source/drain patterns SD are formed on the active pattern AP of the substrate 105.

The first interlayer insulating layer 110 is formed to cover the source/drain patterns SD, the device isolation layer ST, and the gate spacers GS. The second interlayer insulating layer 112 is formed on the first interlayer insulating layer 110. The gate capping pattern GP is formed between the gate spacers GS. A sacrificial insulating layer 201 is formed on the first interlayer insulating layer 110, the second interlayer insulating layer 112, the gate spacer GS, and the gate capping pattern GP. The sacrificial insulating layer 201 includes an insulating material.

A first opening op1 and a second opening op2 are formed by partially removing the first interlayer insulating layer 110, the second interlayer insulating layer 112, the gate spacer GS, the gate capping pattern GP, and the sacrificial insulating layer 201. For example, the first interlayer insulating layer 110 is partially removed to expose a top surface of the source/drain pattern SD. The source/drain pattern SD with the exposed top surface may be defined as the intervening source/drain pattern SDa. The first opening op1 is an empty space that is formed by the partial removal of the first interlayer insulating layer 110, the second interlayer insulating layer 112, the gate spacer GS, the gate capping pattern GP, and the sacrificial insulating layer 201. The second opening op2 is an empty space that is formed by the partial removal of the second interlayer insulating layer 112 and the sacrificial insulating layer 201. In an embodiment, the partial removal of the first interlayer insulating layer 110, the second interlayer insulating layer 112, the gate spacer GS, the gate capping pattern GP, and the sacrificial insulating layer 201 is performed by a dry etching process.

A first preliminary insulating layer p1 is formed in the first opening op1 and the second opening op2. The first preliminary insulating layer p1 conformally covers surfaces of the first interlayer insulating layer 110, the second interlayer insulating layer 112, the gate spacer GS, the gate capping pattern GP and the sacrificial insulating layer 201 that are exposed through the first opening op1, a top surface of the sacrificial insulating layer 201, and a top surface of the intervening source/drain pattern SDa. The first preliminary insulating layer p1 is in contact with the intervening source/drain pattern SDa. The first preliminary insulating layer p1 conformally covers a surface of the second interlayer insulating layer 112 that is exposed by the second opening op2, a surface of the sacrificial insulating layer 201 that is exposed by the second opening op2, and the top surface of the sacrificial insulating layer 201. The first preliminary insulating layer p1 includes an insulating material. For example, the first preliminary insulating layer p1 is formed of or includes at least one oxide material.

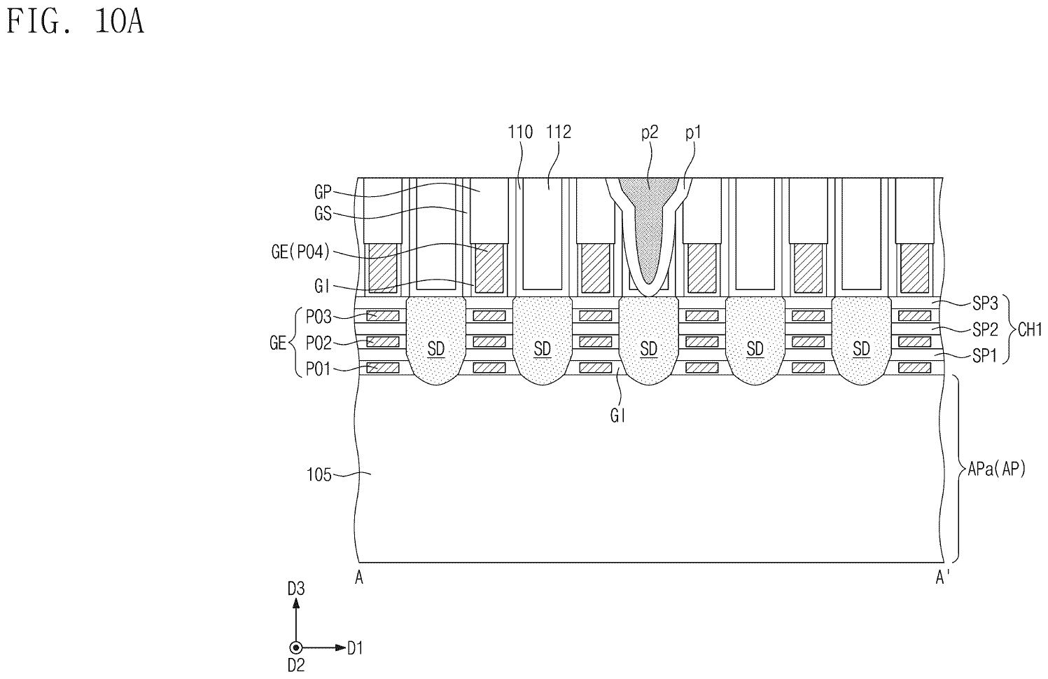

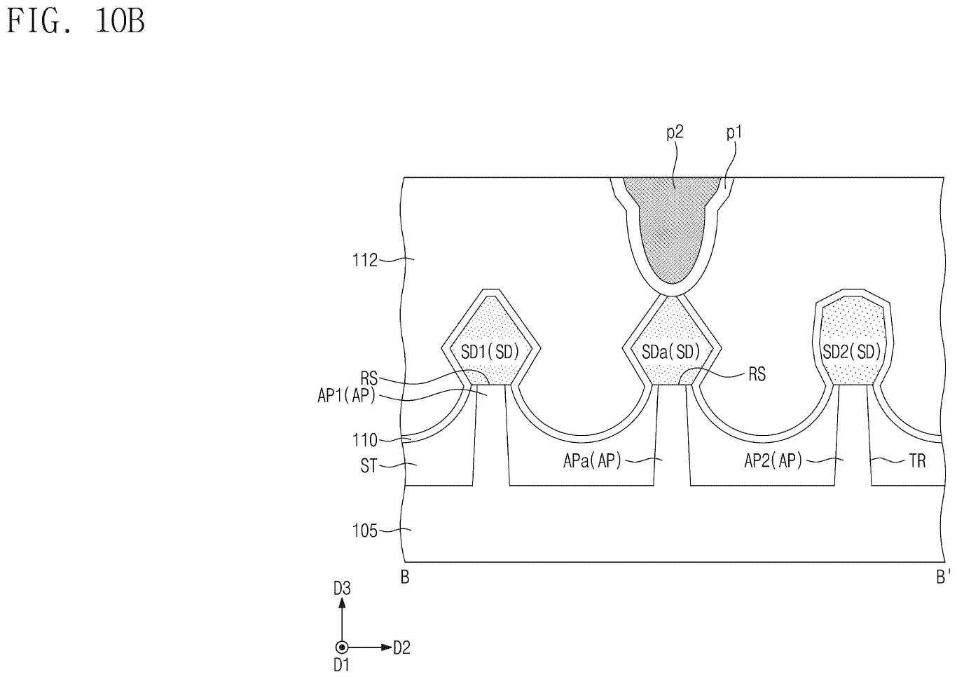

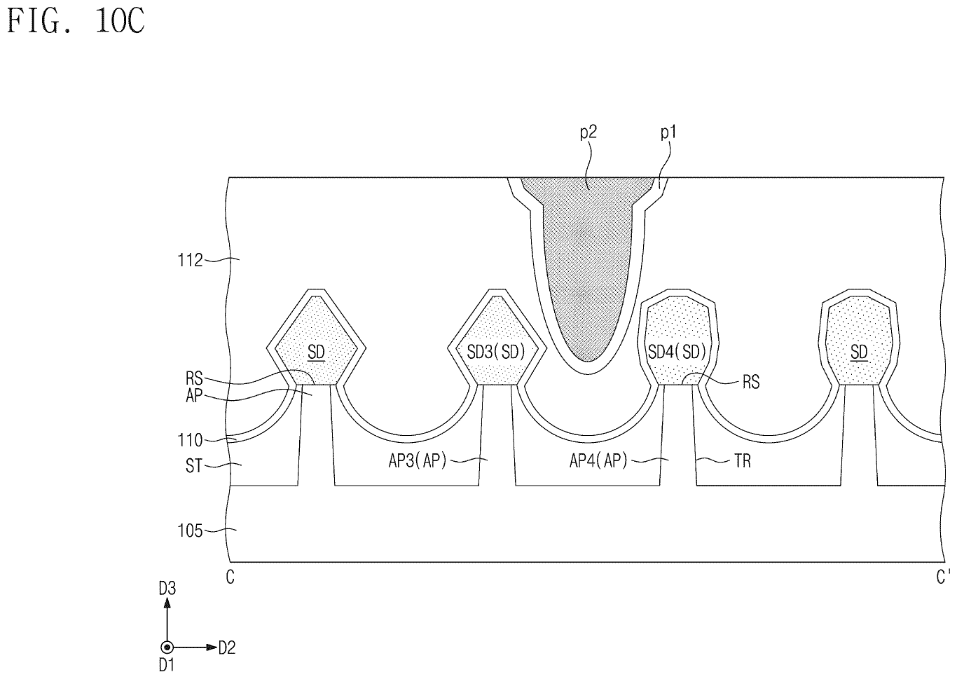

Referring to FIGS. 10A, 10B, and 10C, in an embodiment, a second preliminary insulating layer p2 is formed on the first preliminary insulating layer p1. In an embodiment, the second preliminary insulating layer p2 is formed to fill the first opening op1 and the second opening op2. The second preliminary insulating layer p2 includes an insulating material. For example, the second preliminary insulating layer p2 is formed of or includes at least one nitride material.

A portion of the first preliminary insulating layer p1, a portion of the second preliminary insulating layer p2, and the sacrificial insulating layer 201 are removed. As a result, the first interlayer insulating layer 110, the second interlayer insulating layer 112, the gate spacer GS, and the gate capping pattern GP are exposed. In an embodiment, the first interlayer insulating layer 110, the second interlayer insulating layer 112, the gate spacer GS, and the gate capping pattern GP are also partially removed during the removal process.

In an embodiment, the removal process of the first and second preliminary insulating layers p1 and p2 and the sacrificial insulating layer 201 is performed using a chemical mechanical polishing process. In an embodiment, the first preliminary insulating layer p1, the second preliminary insulating layer p2, the first interlayer insulating layer 110, the second interlayer insulating layer 112, the gate capping pattern GP, and the gate spacer GS are formed to have top surfaces that are substantially coplanar with each other.

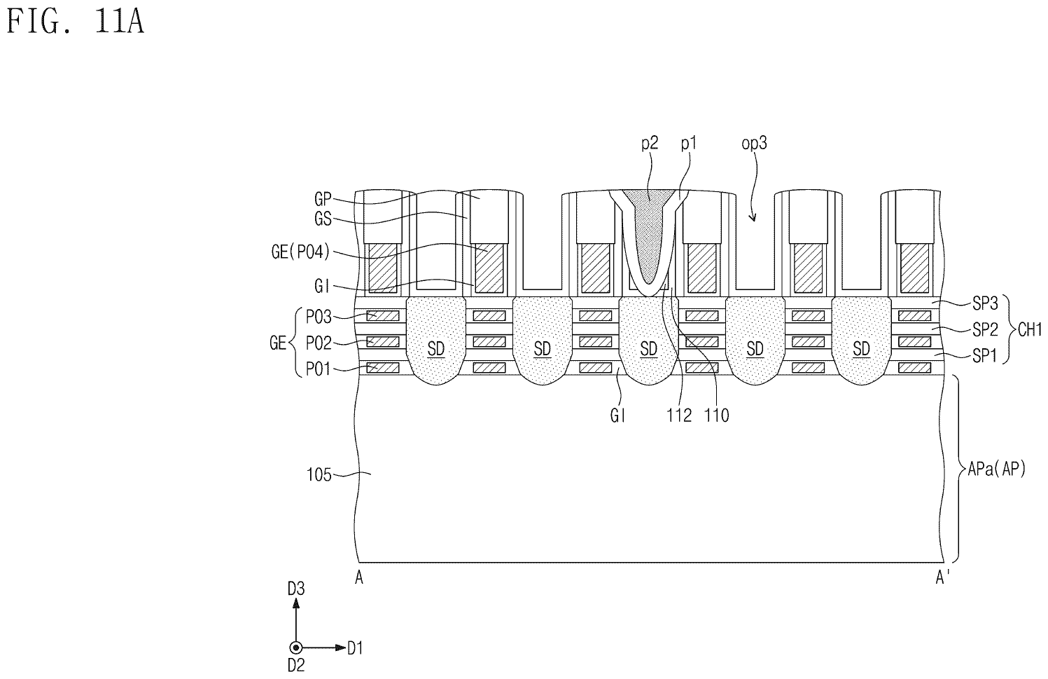

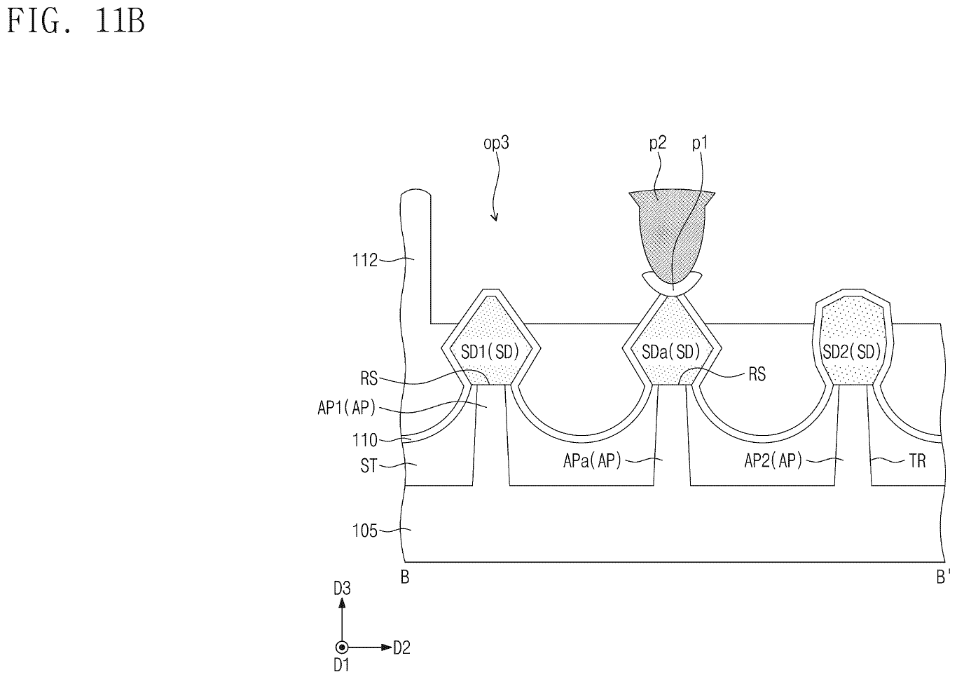

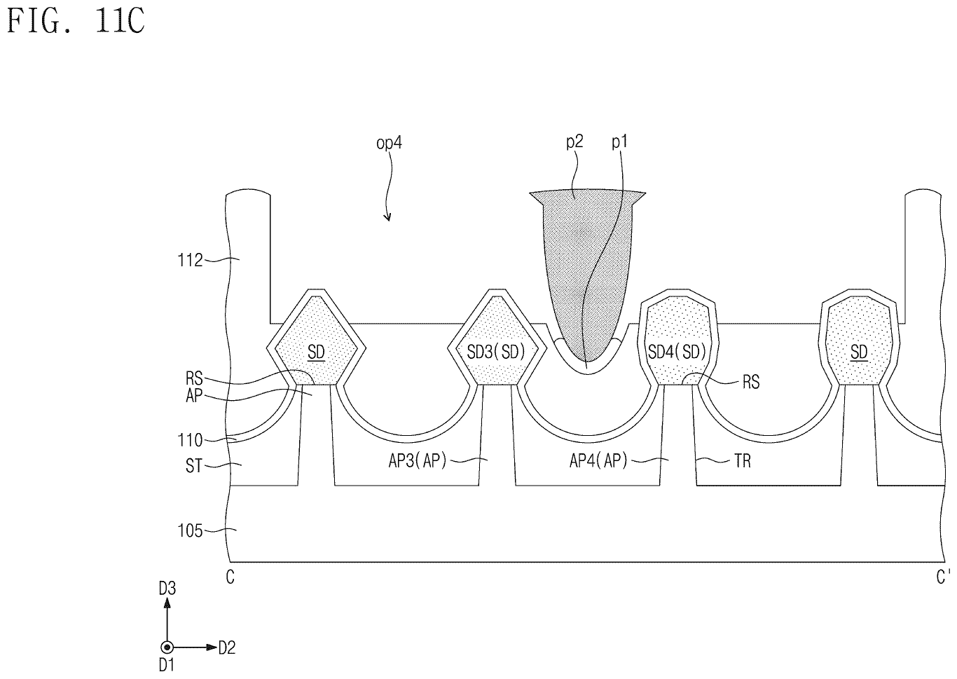

Referring to FIGS. 11A, 11B, and 11C, in an embodiment, the second interlayer insulating layer 112 and the first preliminary insulating layer p1 are partially removed. As a result, a third opening op3 and a fourth opening op4 are formed. The partial removal of the second interlayer insulating layer 112 and the first preliminary insulating layer p1 exposes the first interlayer insulating layer 110, the second interlayer insulating layer 112, the first preliminary insulating layer p1, and the second preliminary insulating layer p2. The third opening op3 is defined by an exposed surface of the second interlayer insulating layer 112. The fourth opening op4 is defined by exposed surfaces of the first interlayer insulating layer 110, the second interlayer insulating layer 112, the first preliminary insulating layer p1, and the second preliminary insulating layer p2.

In an embodiment, the partial removal of the second interlayer insulating layer 112 is performed using a dry etching process. The first preliminary insulating layer p1 has a high etch selectivity with respect to the second preliminary insulating layer p2. Thus, the first preliminary insulating layer p1 is also partially removed by the partial removal process of the second interlayer insulating layer 112. Since the first preliminary insulating layer p1 is partially removed, a surface of the second preliminary insulating layer p2 is externally exposed.

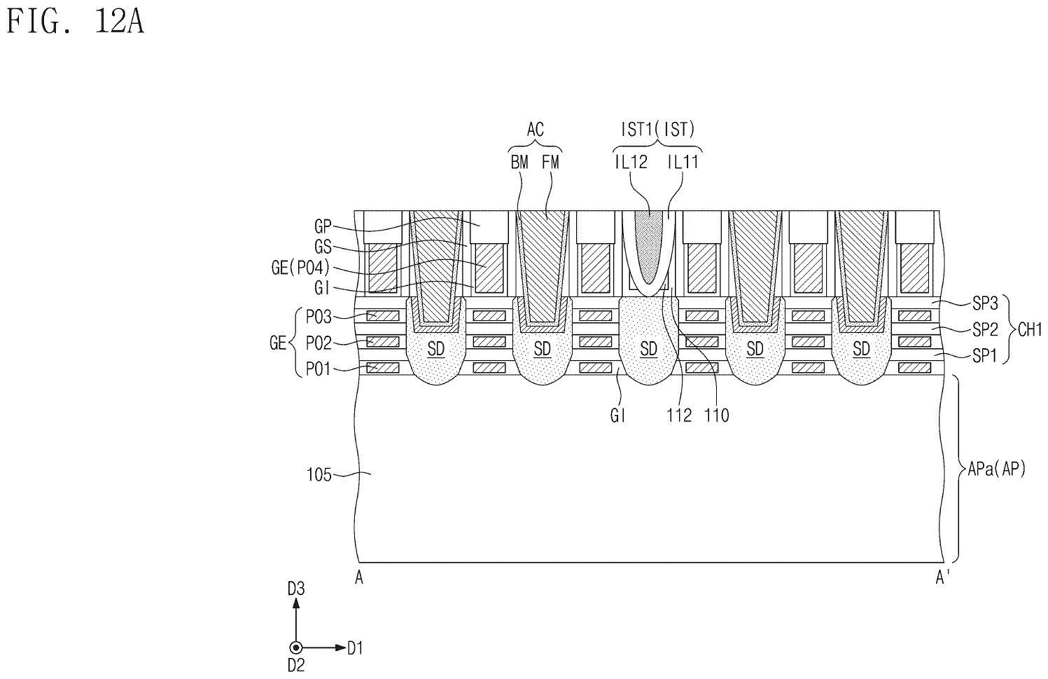

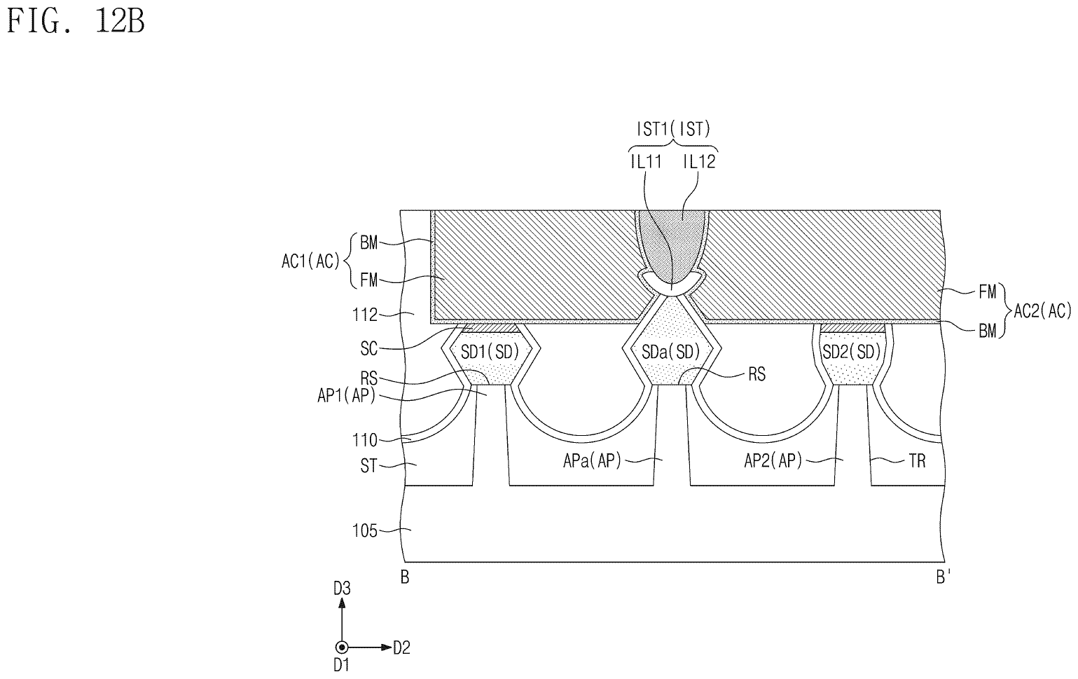

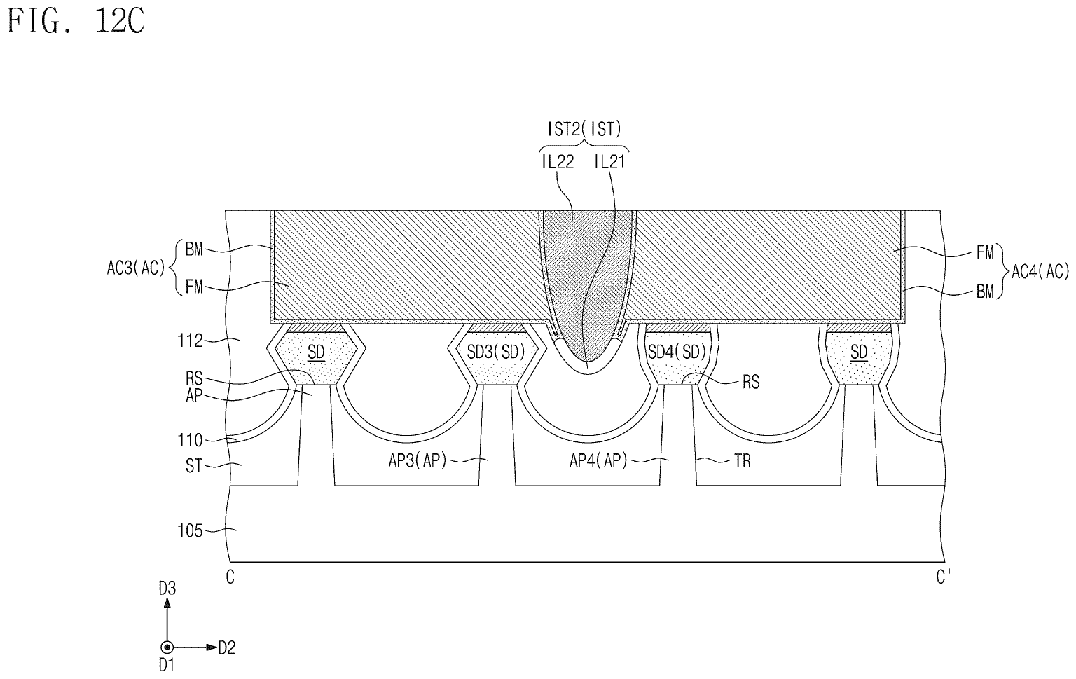

Referring to FIGS. 12A, 12B, and 12C, in an embodiment, the active contacts AC are formed in the third and fourth openings op3 and op4. The formation of the active contacts AC includes removing a portion of the first interlayer insulating layer 110 from the third and fourth openings op3 and op4, a portion of the source/drain pattern SD, forming the metal-semiconductor compound layers SC, forming the barrier layer BM, and forming the conductive pattern FM on the barrier layer BM. The barrier layer BM conformally covers the metal-semiconductor compound layers SC, the first interlayer insulating layer 110, the second interlayer insulating layer 112, the first preliminary insulating layer p1, and the second preliminary insulating layer p2.

In an embodiment, the portion of the first interlayer insulating layer 110 and the portion of the source/drain pattern SD are removed by a contact epi recess (CER) process.

The first interlayer insulating layer 110, the second interlayer insulating layer 112, the first preliminary insulating layer p1, the second preliminary insulating layer p2, the barrier layer BM, and the conductive pattern FM are partially removed, after forming the active contacts AC.

As a result of the partial removal of the first and second preliminary insulating layers p1 and p2, the first and second insulating structures IST1 and IST2 are formed. The first preliminary insulating layer p1, which is partially removed, may be defined as the first insulating layer IL11 of the first insulating structure IST1 and the first insulating layer IL21 of the second insulating structure IST2. The second preliminary insulating layer p2, which is partially removed, may be defined as the second insulating layer IL12 of the first insulating structure IST1 and the second insulating layer IL22 of the second insulating structure IST2.

In an embodiment, the first interlayer insulating layer 110, the second interlayer insulating layer 112, the first preliminary insulating layer p1, the second preliminary insulating layer p2, the barrier layer BM, and the conductive pattern FM are partially removed by a chemical mechanical polishing process. In an embodiment, a top surface of the first insulating structure IST1 and a top surface of the second insulating layer IL22 of the second insulating structure IST2 are coplanar with the top surfaces of the first interlayer insulating layer 110, the second interlayer insulating layer 112, the barrier layer BM, and the conductive pattern FM.

Referring back to FIGS. 5A to 5C, the third interlayer insulating layer 130 is formed on the active contacts AC, the first insulating structure IST1, the second insulating structure IST2, and the second interlayer insulating layer 112. The first metal layer M1 is formed in the third interlayer insulating layer 130. The fourth interlayer insulating layer 140 is formed on the third interlayer insulating layer 130. The second metal layer M2 is formed in the fourth interlayer insulating layer 140.

In a fabrication method according to an embodiment of the inventive concept, since the first preliminary insulating layer p1 has an etch selectivity with respect to the second preliminary insulating layer p2, the removal of the second interlayer insulating layer 112 can be performed to selectively remove a portion of the first preliminary insulating layer p1, while preventing the second preliminary insulating layer p2 from being removed. The active contact AC is formed to fill an empty space that is formed by the partial removal of the first preliminary insulating layer p1, and thus, the size of the active contact AC can be increased. For example, an electric resistance of the active contact AC is reduced, and as a result, the electric performance of the semiconductor device is improved.

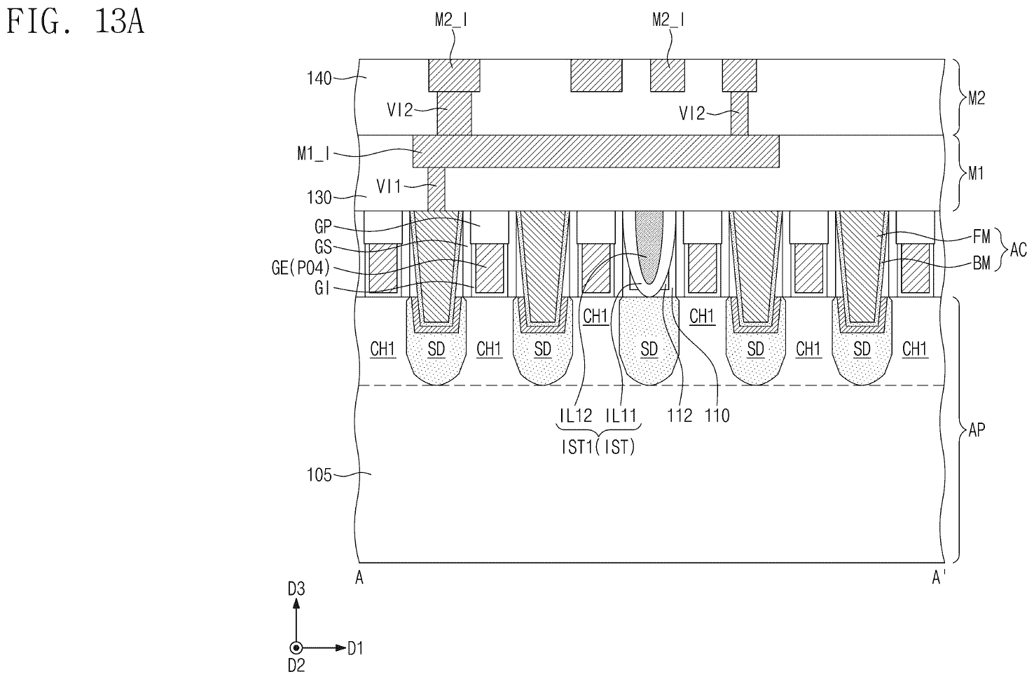

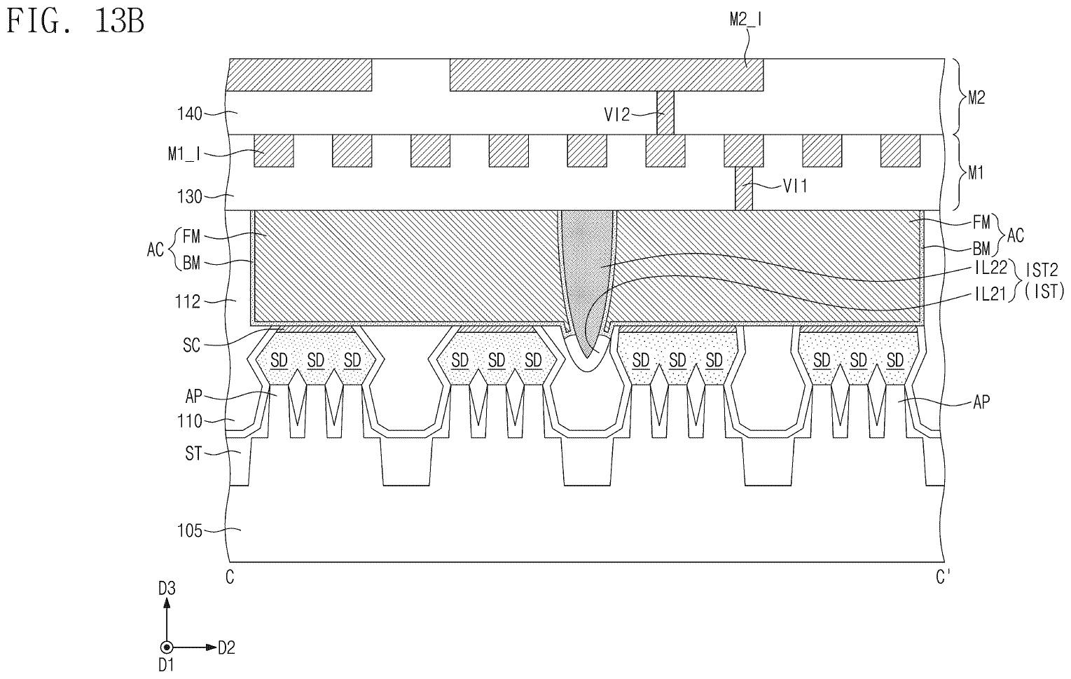

FIG. 13A is a cross-sectional view of a semiconductor device according to an embodiment of the inventive concept. FIG. 13B is a cross-sectional view of a semiconductor device according to an embodiment of the inventive concept. FIG. 13A is a cross-sectional view taken along a line A-A′ of FIG. 4. FIG. 13B is a cross-sectional view taken along a line C-C′ of FIG. 4. A semiconductor device of FIGS. 13A and 13B has similar features to a semiconductor device of FIGS. 5A to 5E, except for the features to be described below.

Referring to FIGS. 4 and 13A to 13B, in an embodiment, the device isolation layer ST defines the active pattern AP in an upper portion of the substrate 105. The active pattern AP includes the source/drain patterns SD that are disposed in an upper portion thereof, and the channel pattern CH1 that is disposed between the source/drain patterns SD.

The channel pattern CH1 does not include the stack of the first to third semiconductor patterns SP1, SP2, and SP3 previously described with reference to FIG. 5A to 5E. The channel pattern CH1 are provided as a single semiconductor pillar that protrudes in an upward direction relative to the device isolation layer ST.

The gate electrode GE is disposed on a top surface of the channel pattern CH1. For example, a transistor according to a present embodiment is a three-dimensional field-effect transistor, such as a FinFET, in which the gate electrode GE three-dimensionally surrounds the channel pattern.

The first and second interlayer insulating layers 110 and 112 are disposed on the device isolation layer ST and the source/drain patterns SD. The active contacts AC penetrate the second interlayer insulating layers 112 and are connected to the source/drain patterns SD. The first insulating structures IST1 penetrate the first and second interlayer insulating layers 110 and 112 and are in contact with the source/drain patterns SD. The second insulating structure IST2 are in contact with a pair of the active contacts AC adjacent to each other in the second direction D2. The active contacts AC, the first insulating structures IST1, and the second insulating structure IST2 have substantially the same features as those in an embodiment described with reference to FIGS. 5A to 5E.

The third interlayer insulating layer 130 is disposed on the second interlayer insulating layer 112. The fourth interlayer insulating layer 140 is disposed on the third interlayer insulating layer 130. The first metal layer M1 is disposed in the third interlayer insulating layer 130. The second metal layer M2 is disposed in the fourth interlayer insulating layer 140. The first and second metal layers M1 and M2 have substantially the same features as those in an embodiment described with reference to FIGS. 5A to 5F.

According to an embodiment of the inventive concept, a semiconductor device includes an insulating structure disposed between adjacent active contacts, which improves resistance characteristics between the active contacts and the electrical characteristics of the semiconductor device.

Furthermore, the active contacts include an intervening portion, and thus, the size of the active contact is increased. This can improve the resistance characteristics of the active contact and therefore enhance the electrical characteristics of the semiconductor device.

While embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a first active pattern that extends in a first direction;
a second active pattern spaced apart from the first active pattern in a second direction that crosses the first direction;
a first source/drain pattern disposed on the first active pattern;
a second source/drain pattern disposed on the second active pattern;
a first active contact electrically connected to the first source/drain pattern;
a second active contact electrically connected to the second source/drain pattern; and
an insulating structure disposed between the first and second active contacts,
wherein the insulating structure includes a first insulating layer and a second insulating layer disposed on the first insulating layer, and
each of the first and second insulating layers is in contact with the first and second active contacts.

2. The semiconductor device of claim 1, further comprising:
a third active pattern disposed between the first active pattern and the second active pattern; and
an intervening source/drain pattern disposed on the third active pattern,
wherein the intervening source/drain pattern is spaced apart from the first and second active contacts.

3. The semiconductor device of claim 2, wherein the first insulating layer comprises a curved surface in contact with the intervening source/drain pattern.

4. The semiconductor device of claim 3, wherein the curved surface of the first insulating layer protrudes toward the intervening source/drain pattern.

5. The semiconductor device of claim 2, wherein
the intervening source/drain pattern comprises an upper portion in contact with the first insulating layer, and
the upper portion of the intervening source/drain pattern is disposed between the first and second active contacts.

6. The semiconductor device of claim 1, wherein a level of a lowermost portion of the first insulating layer is higher than a level of a lowermost portion of the first and second active contacts.

7. The semiconductor device of claim 1, wherein the first insulating layer comprises a material that has an etch selectivity with respect to the second insulating layer.

8. The semiconductor device of claim 1, wherein a level of a lowermost portion of the first insulating layer is lower than a level of a lowermost portion of the first and second active contacts.

9. The semiconductor device of claim 1, further comprising:
a first interlayer insulating layer disposed on the first source/drain pattern and the second source/drain pattern; and
a second interlayer insulating layer disposed on the first interlayer insulating layer,
wherein the first insulating layer comprises a curved surface in contact with the second interlayer insulating layer.

10. The semiconductor device of claim 9, wherein the curved surface of the first insulating layer is disposed between the first source/drain pattern and the second source/drain pattern.

11. The semiconductor device of claim 9, wherein the curved surface of the first insulating layer is in contact with the first source/drain pattern and the second source/drain pattern.

12. The semiconductor device of claim 9, wherein
the first active contact comprises a conductive pattern and a barrier layer that encloses the conductive pattern,
the conductive pattern comprises an intervening portion that protrudes toward the first insulating layer, and
the intervening portion is interposed between the second insulating layer and the first source/drain pattern.

13. A semiconductor device, comprising:
a first active pattern that extends in a first direction;
a second active pattern spaced apart from the first active pattern in a second direction that crosses the first direction;
a first source/drain pattern disposed on the first active pattern;
a second source/drain pattern disposed on the second active pattern;
a first active contact electrically connected to the first source/drain pattern;
a second active contact electrically connected to the second source/drain pattern; and
an insulating structure disposed between the first and second active contacts,
wherein the insulating structure includes a first insulating layer and a second insulating layer disposed on the first insulating layer,
wherein the second insulating layer comprises:
a first surface in contact with the first insulating layer; and
a second surface in contact with the first and second active contacts.

14. The semiconductor device of claim 13, further comprising:
a third active pattern disposed between the first active pattern and the second active pattern; and
a first intervening source/drain pattern disposed on the third active pattern,
wherein the first insulating layer includes a first curved surface in contact with the first intervening source/drain pattern.

15. The semiconductor device of claim 14, further comprising
a second intervening source/drain pattern adjacent to the first intervening source/drain pattern,
wherein the first insulating layer comprises:
a second curved surface in contact with the second intervening source/drain pattern; and
a connection surface that connects the first curved surface to the second curved surface.

16. The semiconductor device of claim 15, further comprising:
a gate electrode disposed between the first curved surface and the second curved surface; and
a gate capping pattern disposed on the gate electrode,
wherein the gate capping pattern is in contact with the connection surface.

17. The semiconductor device of claim 14, wherein
the insulating structure further includes a third insulating layer enclosed by the second insulating layer, and
the first to third insulating layers include different insulating materials from each other.

18. The semiconductor device of claim 13, wherein a level of the first surface is lower than a level of the first and second active contacts.

19. A semiconductor device, comprising:
a first active pattern that extends in a first direction;
a second active pattern spaced apart from the first active pattern in a second direction that crosses the first direction;
a first source/drain pattern disposed on the first active pattern;
a second source/drain pattern disposed on the second active pattern;
a first active contact electrically connected to the first source/drain pattern;
a second active contact electrically connected to the second source/drain pattern;
a device isolation layer disposed on the first and second active patterns;
a first interlayer insulating layer disposed on the first source/drain pattern, the second source/drain pattern, and the device isolation layer;
a second interlayer insulating layer disposed on the first interlayer insulating layer; and
an insulating structure disposed between the first and second active contacts,
wherein the insulating structure includes a first insulating layer and a second insulating layer disposed on the first insulating layer,
each of the first and second active contacts includes a conductive pattern and a barrier layer that encloses the conductive pattern,
wherein the first insulating layer comprises:
an inner surface in contact with the second insulating layer;
a curved surface in contact with the first and second interlayer insulating layers; and
a connection surface that connects the inner surface to the curved surface,
wherein the connection surface of the first insulating layer is in contact with the barrier layers of the first and second active contacts.

20. The semiconductor device of claim 19, further comprising:
a third active pattern disposed between the first active pattern and the second active pattern;
an intervening source/drain pattern disposed on the third active pattern;
a third source/drain pattern adjacent to the intervening source/drain pattern in the first direction; and
a plurality of semiconductor patterns that are stacked between the intervening source/drain pattern and the third source/drain pattern and that are spaced apart from each other.
